(19) United States
(12) Patent Application Publication
(10) Pub. No.: US 2026/0352970 A1
(43) Pub. Date: Nov. 5, 2026

(54) IMAGE SENSOR AND METHOD OF FORMING THE SAME

(71) Applicant: Taiwan Semiconductor Manufacturing Company, Ltd., Hsinchu (TW)

(72) Inventors: Chieh-En Chen, Tainan City (TW); Chen-Hsien Lin, Tainan City (TW); Shyh-Fann Ting, Tainan City (TW)

(21) Appl. No.: 19/742,147

(22) Filed: Jul. 15, 2026

Related U.S. Application Data
(62) Division of application No. 18/887,353, filed on Sep. 17, 2024.

(51) Int. Cl. H04N 25/59; H04N 25/78; H10F 39/00

(52) U.S. Cl. CPC H04N 25/59; H04N 25/78; H10F 39/014; H10F 39/811

(57) ABSTRACT

An image sensor has a three device layers. Through substrate MIM (TSMIM) capacitors are disposed in the middle device layer. The TSMIM capacitors may replace capacitors that would otherwise be disposed in the metal interconnect structure of the second device layer allowing that metal interconnect structure, particularly the uppermost metallization layer, to be thinner. Thinning that upper metallization layer reduces parasitic capacitance and increases dynamic range. The TSMIM capacitors may be correlated double sampling (CDS) capacitors, lateral overflow integration capacitors (LOFICs), or any other type of capacitor used in a photodetector circuit.

### REFERENCE TO RELATED APPLICATION

This Application is a Divisional of U.S. application Ser. No. 18/887,353, filed on Sep. 17, 2024, the contents of which are hereby incorporated by reference in their entirety.

### BACKGROUND

Many modern day electronic devices (e.g., digital cameras, optical imaging devices, etc.) comprise image sensors. An image sensor includes an array of photosensitive structures which transduce light into electrical charge. Examples of image sensors include charge-coupled device (CCD) image sensors and complementary metal-oxide-semiconductor (CMOS) image sensors. Compared to CCD image sensors, CMOS image sensors are favored due to low power consumption, small size, fast data processing, a direct output of data, and low manufacturing cost.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1A illustrates a cross-sectional view of an image sensor in accordance with some embodiments.

FIG. 1B provides an expanded view of the area B in FIG. 1A.

FIGS. 2-3 illustrate layouts in accordance with some embodiments for the second device layer in the image sensor of FIG. 1A

FIG. 4 provides a circuit diagram for an image sensor in accordance with some embodiments.

FIGS. 5A-35 provide a series of cross-sectional views illustrating an embodiment of a manufacturing process according to the present disclosure.

FIG. 36 is a flow chart of a process in accordance with some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

One type of CMOS image sensor has an array of photodetectors each of which includes a photosensitive area within a semiconductor substrate, a transfer gate, a floating diffusion node, a source follower, a row select transistor, and a reset transistor. When the reset transistor is closed, the floating diffusion node is charged to a reference voltage. Light is transduced into electrical charges within the photosensitive area(s). The charges accumulate until the transfer gate is closed allowing them to flow to the floating diffusion node. The charges alter the floating diffusion node voltage. When the row select transistor is closed, current flows through the source follower and the row select transistor. The magnitude of that current depends on the floating diffusion node voltage, which is applied to the source follower gate electrode. The current is detected and used to infer the amount of charge that was transferred to the floating diffusion node, which in turn reflects the amount of radiation that was incident on the photosensitive area over the sampling interval.

Conversion gain is a significant parameter in a CMOS image sensor of the type just described. The conversion gain is related to the capacitance of the floating diffusion node. The capacitance of the floating diffusion node includes contributions from a floating diffusion region, which is the drain region of the transfer gate, the source region of the reset transistor, the gate electrode of the source follower, and parasitic capacitance associated with wiring that connects these structures. If the capacitance is too high conversion gain will be too low, there will be excessive noise in the signal, and variations in light intensity at low levels of illumination will be lost.

Another significant performance parameter for a CMOS image sensor is resolution. High resolution is achieved through high pixel density. The area occupied by transistors in the photodetector pixel circuit can limit pixel density. One approach to overcoming that limitation is use two-or three-device layers. A portion of the photodetector pixel circuit can be located on the second device layer to reduce pixel area and allow a higher pixel density. An application-specific integrated circuit (ASIC) may be disposed in the peripheral region of the second device layer or in a third device layer.

A shortcoming of the two-or three-device layer approach is that the wiring that connects the floating diffusion node to the second device layer adds capacitance to the floating diffusion node. That added capacitance reduces conversion gain, increases noise, and lowers dynamic range. It has been found that the much of that added capacitance is the result of parasitic capacitance in the uppermost metallization layer of the second device layer. The uppermost metallization layer of the second device layer is ordinarily much thicker than other metallization layers in order to accommodate capacitors. Those capacitors typically include correlated double sampling (CDS) capacitors in correlated double sample circuits. CDS circuits capacitors improve image quality by canceling fixed pattern and thermal noise. The CDS circuits may be in column readout circuits (column readout systems) in the second device layer.

Another type of capacitor commonly used in CMOS image sensors is a later overflow integration capacitor (LOFIC). An LOFIC may be added to the photodetector pixel circuit along with a dual conversion gain (DCG) transistor to implement DCG. DCG increases dynamic range by allowing the photodetector to be switched between a low conversion gain mode and a high conversion gain mode. The low conversion gain mode is used to discriminate images at high light intensity levels. In the low conversion gain mode, the LOFIC is coupled to the floating diffusion node through the DCG transistor. In the high conversion gain mode, the DCG transistor is open so that the LOFIC is isolated from the floating diffusion node. The LOFIC may be even larger than a CDS capacitor, which further motivates the increased thickness of the uppermost metallization layer in the second device layer.

The present disclosure solves the problem of excessive parasitic capacitance by replacing capacitors in the upper metallization layer of the second device layer with MIM capacitors formed through the substrate of the second device layer. This allows the upper metallization layer of the second device layer to be much thinner; similar in thickness to the other metallization layers. In some embodiments, the upper metallization layer has a thickness no more than about 50% greater than that of any other metallization layer in the second device layer. The second device layer often includes through substrate vias (TSVs) that couple the second and third device layers. Through substrate MIM (TSMIM) capacitors can be added alongside the TSVs without significantly altering the process flow or making far reaching and costly changes to the overall image sensor design.

In a manufacturing process of the present disclosure, a first device layer and a second device layer are bonded together after having undergone front-end-of line (FEOL) and back-end-of-line processing (BEOL). The first and second device layers comprise semiconductor substrates. FEOL processing of the first device semiconductor substrate forms an array of photodiodes or some other photosensitive structures, associated transfer gates, and/or the like. FEOL processing of the second semiconductor substrate forms one or more in-pixel transistors for the photodetector circuits. BEOL processing forms metal interconnect structures on the semiconductor substrates. The metal interconnect structures comprise pluralities of metallization layers. The second semiconductor substrate is thinned from the back side followed by formation of TSVs and TSMIM capacitors. In some embodiments, the TSVs are formed before the TSMIM capacitors. That order of formation results in fewer material layers and a more reliable manufacturing process.

Forming the TSMIM capacitors comprises etching trenches through the second semiconductor substrate beginning from the back side of the second semiconductor substrate. Because the trenches are formed from the back side, the TSMIM capacitors are narrower at the front side than at the back side. The trenches may be extended into the metal interconnect structure on the front side so that the TSMIM capacitors have bottom plates contacting wires in the metal interconnect structure on the front side.

In some embodiments, vias and contacts pads corresponding to and coupling to the TSMIM capacitors and the TSVs are formed on the back side. The second device layer with the first device layer attached may then be bonded to a third device layer that makes connections with the contact pads. The third device layer may include an ASIC and may provide routing for the TSVs and the TSMIM capacitors. In some embodiments, at least one of the TSMIM capacitors is coupled to a TSV through the metal interconnect structure of the third device layer. In some embodiments, at least one of the TSMIM capacitors is coupled to a transistor on a semiconductor substrate in the third device layer.

After attachment of the second device layer to the third device layer, the first semiconductor substrate may be thinned from its back side. Thinning the substrate allows for back side illumination with high image capture efficiency. After thinning, color filters and microlenses may be formed on the back side.

In some embodiments, one of the TSMIM capacitors is a CDS capacitor. In some embodiments, the TSMIM capacitors include an array of LOFICs. In some embodiments, the photodetector pixel circuits are configured so that there is one LOFIC for every four photosensitive regions. For example, a photodetector pixel circuits may include four transfer gates coupled to one floating diffusion node. The floating diffusion node may be selectively coupled to an LOFIC in the second device layer. It may be difficult to form a TSMIM capacitor within the area allotted for a single photosensitive area. Having four photosensitive areas for each photodetector pixel circuit facilitates using a TSMIM capacitor within the photodetector pixel circuit.

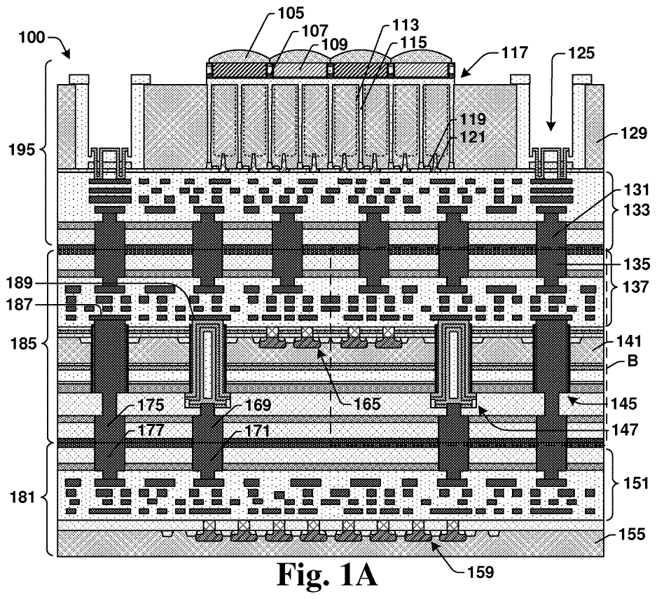

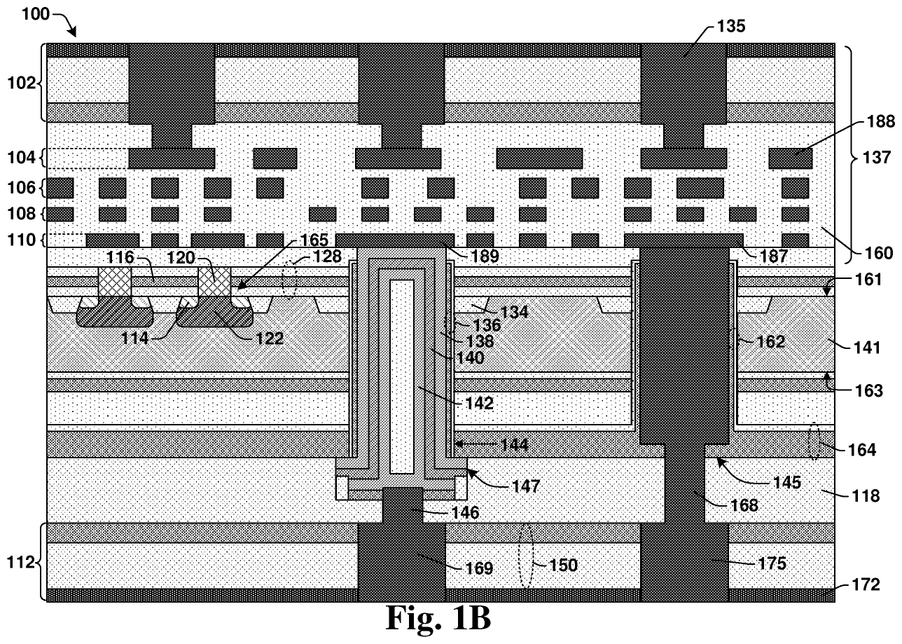

FIG. 1A illustrates a cross-sectional view of an image sensor 100 in accordance with some embodiments. The image sensor 100 includes three device layers: a first device layer 195 comprising a first semiconductor substrate 129 and a first metal interconnect structure 133, a second device layer 185 comprising a second semiconductor substrate 141 and a second metal interconnect structure 137, and a third device layer 181 comprising a third semiconductor substrate 155 and a third metal interconnect structure 151.

The first device layer 195 includes an array 117 of photodiodes 113 or other photosensitive structures that transduce light into electrical charges. Transfer gates 121 and floating diffusion regions 119 may be disposed proximate a front side of the first semiconductor substrate 129. The floating diffusion regions 119 are coupled to other photodetector pixel circuit components such as transistors 165 through the first metal interconnect structure 133 and the second metal interconnect structure 137.

TSMIM capacitors 147 and TSVs 145 are disposed in the second device layer 185 and extend through the second semiconductor substrate 141. The TSMIM capacitors 147 are connected between wires 189 in the second metal interconnect structure 137 and contact pads 169. The contact pads 169 are coupled to contact pads 171 of the third device layer 181. The TSVs 145 are connected between wires 187 in the second metal interconnect structure 137 and contact pads 175. The contact pads 175 are coupled to contact pads 177 of the third device layer 181. The third device layer 181 may contain transistors 159 and other components of an ASIC. In some embodiments, the TSMIM capacitors 147 are CDS capacitors and there is one CDS capacitor for each column in the array 117. In some embodiments, the TSMIM capacitors 147 are LOFICs and there is one TSMIM capacitors 147 for each photodetector pixel circuit. A pixel photodetector circuit may include from one, two, or four of the photodiodes 113.

FIG. 1B provides an expanded view of the area B in FIG. 1A. As can be seen in FIG. 1B, the second metal interconnect structure 137 includes a lowest metallization layer 110, a second lowest metallization layer 108, a next-to-uppermost metallization layer 106, an uppermost metallization layer 104, and a bonding layer 102. The second metal interconnect structure 137 may include metallization layers in addition to the ones that are shown. Each of the lowest metallization layer 110, the second lowest metallization layer 108, the next-to-uppermost metallization layer 106, and the uppermost metallization layer 104 include a plurality of wires 188 surrounded by interlevel dielectric 160. Wires 188 in adjacent metallization layers may be connected by vias (not shown). The metallization layers become progressively thicker from the lowest metallization layer 110 to the uppermost metallization layer 104. If the uppermost metallization layer 104 includes capacitors, it is generally much thicker than the next-to-uppermost metallization layer 106, e.g., about four times as thick. In accordance with the present disclosure, the uppermost metallization layer 104 is not much greater in thickness than the next-to-uppermost metallization layer 106. In some embodiments, the uppermost metallization layer 104 has a thickness of about 200 nm or less. In some embodiments, the uppermost metallization layer 104 has a thickness no more than about twice that of the next-to-uppermost metallization layer 106. In some embodiments, the uppermost metallization layer 104 has a thickness no more than about 50% greater than that of the next-to-uppermost metallization layer 106. In some embodiments, the uppermost metallization layer 104 has a thickness about equal to that of the next-to-uppermost metallization layer 106. If the uppermost metallization layer 104 is too thick, it may increase parasitic capacitance to an undesirable extent. If the uppermost metallization layer 104 is too thin, the conductivity of wires 188 in the uppermost metallization layer 104 may be too low.

The TSMIM capacitors 147 include a first electrode plate 138 and a second electrode plate 142 separated by a capacitor dielectric layer 140. The capacitor dielectric layer 140 may be a high-K dielectric having any suitable thickness. In some embodiments, the capacitor dielectric layer 140 has a thickness in the range from about 5 nm to about 20 nm. In some embodiments, the capacitor dielectric layer 140 has a thickness in the range from about 20 nm to about 40 nm. A thinner capacitor dielectric provides higher capacitance but increases leakage and so limits the operating voltage. Making the capacitor dielectric thicker reduces capacitance but allows higher operating voltages while limiting leakage. Capacitors in the uppermost metallization layer 104 generally have dielectric thicknesses of 20 nm or less and are limited to operating with voltages of about 1.8V or less. If the dielectric were made thicker, it would be difficult to allot sufficient area to provide sufficient capacitance. Forming the capacitors through the second semiconductor substrate 141, on the other hand, allows for more area so that an equivalent capacitance can be achieved with a thicker dielectric that permits a higher operating voltage. In some embodiments, the TSMIM capacitors 147 have operating voltages in the range from about 1.8 V to about 5 V. In some embodiments, the TSMIM capacitors 147 have operating voltages in the range from about 2.5V to about 3.3V. Higher operating voltages allow the image sensor 100 to sense images with less noise.

A first dielectric structure 162 isolates the TSVs 145 from the second semiconductor substrate 141. A second dielectric structure 136 isolates the TSMIM capacitors 147 from the second semiconductor substrate 141. In some embodiments, one or more dielectric layers of the first dielectric structure 162 extend horizontally over the back side 163 of the semiconductor structure and abut a vertical sidewall 144 of the second dielectric structure 136. This configuration is indicative of the TSVs 145 having been formed prior to the TSMIM capacitors 147.

Oxide layer 118 and bonding layer 112 are over the TSVs 145 and the TSMIM capacitors 147 with respect to the back side 163. Vias 146 pass through the oxide layer 118 to couple the TSMIM capacitors 147 to the contact pads 169 in the bonding layer 112. Vias 168 pass through the oxide layer 118 to couple the TSVs 145 to the contact pads 175. In some embodiments, the vias 168 are longer than the vias 146. This structure is easier to manufacture than one in which the vias 146 are longer.

A dielectric structure 128 including an etch stop layer 116 is disposed on the front side 161. Gate electrodes 120 of the transistors 165 may extend through the dielectric structure 128. The transistors 165 have body regions 122 and source/drain regions 114 in the second semiconductor substrate 141. The transistors 165 may be in photodetector pixel circuits.

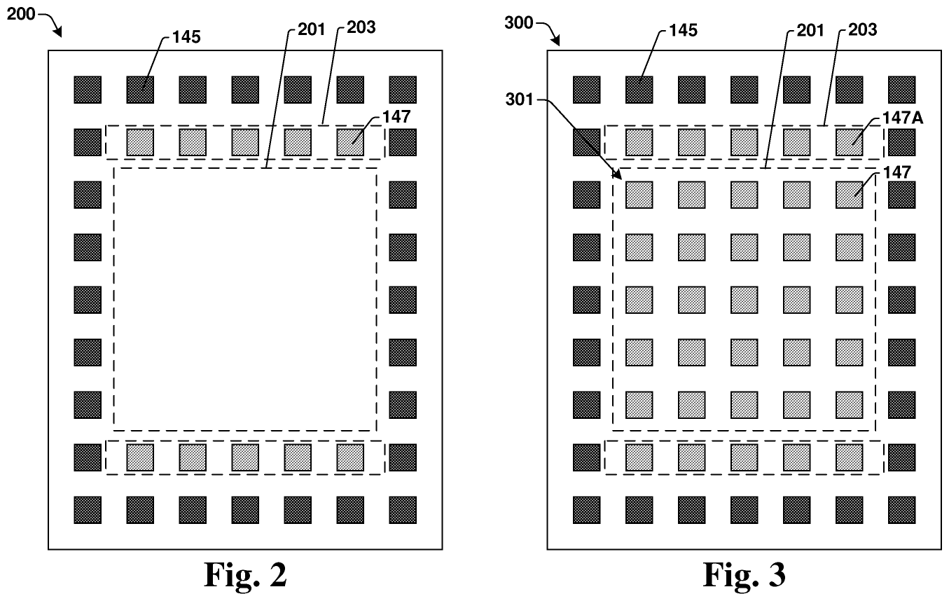

FIG. 2 provides a plan view 200 which, in some embodiments, is a plan view of the second device layer 185 in the image sensor 100 of FIG. 1A. In the plan view 200, the TSMIM capacitors 147 are CDS capacitors in column readout circuits 203. A photodiode area 201 corresponds to an area occupied by the array 117 of photodiode 113 in the first device layer 195 (see FIG. 1A). The photodiodes 113 in the array 117 may be arranged in rows and columns, and the TSMIM capacitors 147 may be positioned at the ends of the columns. The TSVs 145 may be disposed around the perimeter of the second device layer 185.

FIG. 3 provides a plan view 300 which, in some other embodiments, is a plan view of the second device layer 185 in the image sensor 100 of FIG. 1A. In the plan view 300, the TSMIM capacitors 147 may be LOFICs. Additional TSMIM capacitors 147A may provide CDS capacitors. In the plan view 300, the TSMIM capacitors 147 form an array 301 in the photodiode area 201.

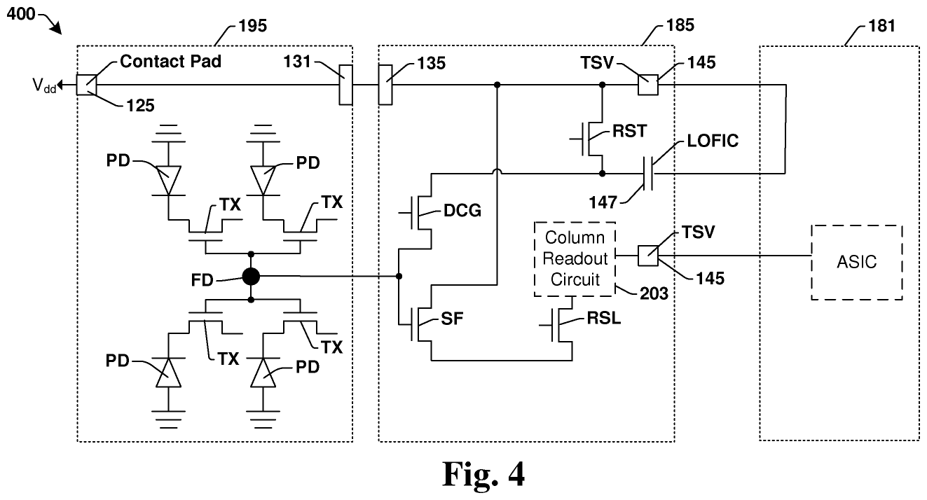

FIG. 4 provides a circuit diagram for a photodetector pixel circuit 400 in accordance with some embodiments. The photodetector pixel circuit 400 includes four photodiodes PD and four transfer gates TX in the first device layer 195; a DCG transistor, a source follower SF, a reset transistor RST, a row select transistor RSL, and an LOFIC in the second device layer 185, and an ASIC in the third device layer 181. A floating diffusion node FD may have components on both the first device layer 195 and the second device layer 185. The LOFIC may be a TSMIM capacitor 147 as shown in FIG. 1A and FIG. 3.

Closing the DCG transistor adds the capacitance of the LOFIC to the floating diffusion node FD. Charges from any of the four photodiodes PD may be transferred to the floating diffusion node FD by operating respective transfer gates TX. Accordingly, only one floating diffusion node and one LOFIC is provided for each four photodiodes PD. This configuration allows the array of TSMIM capacitors 147 (see FIG. 3) to have one fourth the number density of the array 117 of photodiode 113 and thereby facilitates providing the LOFIC capacitors using TSMIM structures.

As shown in FIG. 4 and in FIG. 1A, the TSMIM capacitor 147 has an electrode coupled to the third device layer 181. As shown in FIG. 4, the electrode coupled to the third device layer 181 may be routed to one of the TSVs 145. In some embodiments, the TSV 145 is further routed to the contact pad 125 (see FIG. 1A), e.g., through a contact pad 135 in the second device layer 185 and a contact pad 131 in the first device layer 195. Through the contact pad 125, the electrode may be connected to Vdd.

The photodetector pixel circuit 400 of FIG. 4 shows only one possibility for the connectivity of the electrode of the TSMIM capacitor 147 that is coupled to the third device layer 181. In some embodiments, the electrode is couple to Vss. In some embodiments, the electrode is coupled to one of the transistors 165 (see FIG. 1A) in second device layer 185. In some embodiments, the electrode is coupled to one of the transistors 159 in the third device layer 181.

A TSV 145 may be used to route a connection to an electrode of the TSMIM capacitor 147 from the third device layer 181 to the second device layer 185, however, some of the TSVs 145 typically have other functions. For example, the column readout circuit 203 provides its output to the ASIC in the third device layer 181 through one of the TSVs 145.

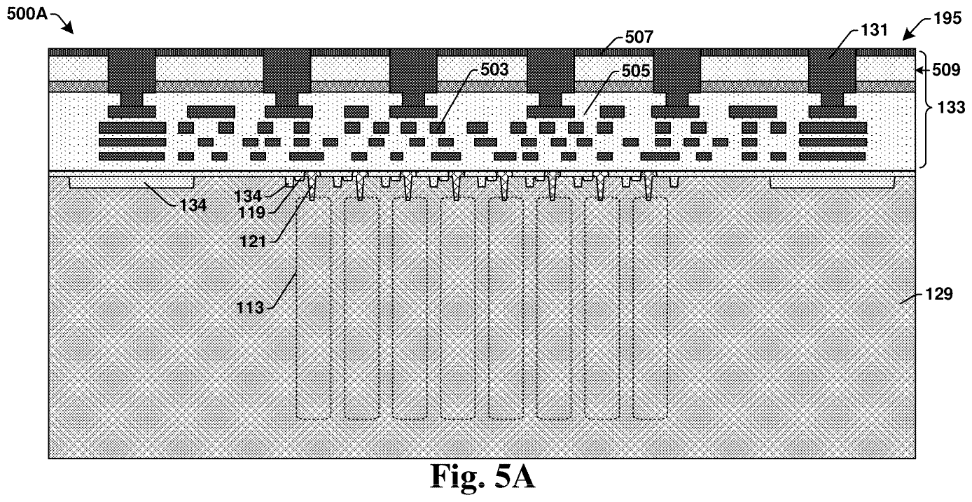

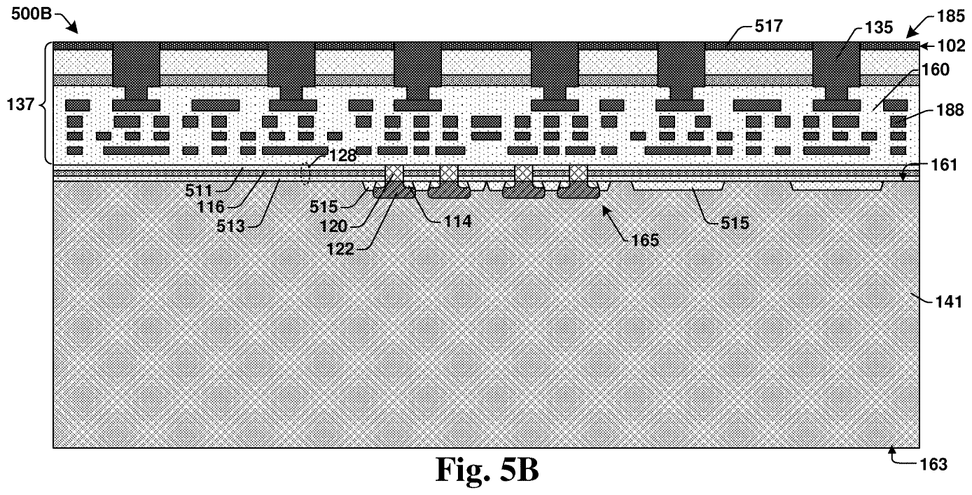

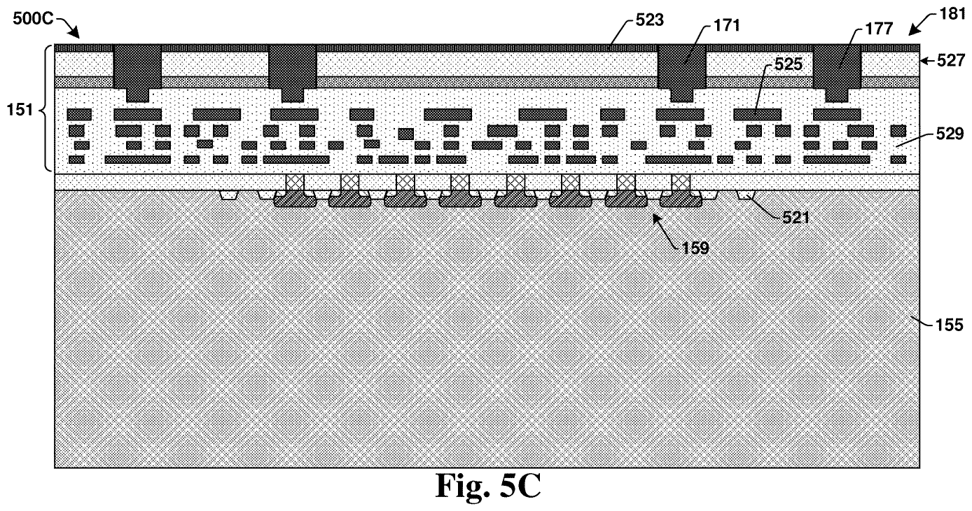

FIGS. 5A-40 illustrate a series of cross-sectional views of components of an image sensor at various stages of manufacture according to a process of the present disclosure. Although FIGS. 5A-40 are described in relation to a series of acts, it will be appreciated that the order of the acts may in some cases be altered and that this series of acts are applicable to structures other than the ones illustrated. In some embodiments, some of these acts may be omitted in whole or in part. Furthermore, although FIGS. 5A-40 are described in relation to a series of acts, it will be appreciated that the structures shown in FIGS. 5A-40 are not limited to a method of manufacture but rather may stand alone as structures separate from the method.

The method may begin with FEOL and BEOL processing for each of the three device layers. FIGS. 5A, 5B, and 5C provide cross-sectional views 500A-500C illustrating the first device layer 195, the second device layer 185, and the third device layer 181 respectively at the conclusion of FEOL and BEOL processing. Up to this point, the three device layers maybe processed separately and in any order.

With reference to the cross-sectional view 500A of FIG. 5A, the first device layer 195 includes the photodiodes 113 which are formed in the first semiconductor substrate 129. The first semiconductor substrate 129 may be a bulk semiconductor substrate or a semiconductor on insulator (SOI) substrate. At least an upper portion of the first semiconductor substrate 129 is a semiconductor. The semiconductor may be, for example, silicon (Si), a group III-V semiconductor or some other binary semiconductor, a tertiary semiconductor (e.g., AlGaAs), a higher order semiconductor, or the like. In some embodiments, the semiconductor is or comprises silicon (Si) or the like. The photodiodes 113 may be formed by ion implantation into the first semiconductor substrate 129 during FEOL processing. Additional structures formed during FEOL processing may include the transfer gates 121, the floating diffusion regions 119, and the isolation structures 134.

The first metal interconnect structure 133 including wires 503 surrounded by interlevel dielectric 505 is formed during BEOL processing. The wires 503 are arranged in a plurality of metallization layers. Vias (not shown) connect wires 503 between adjacent metallization. Wires and vias in a metal interconnect structure may be or comprise copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, the like, or any other suitable conductive materials. Wires and vias may also include diffusion barrier layers such as titanium (Ti), tantalum (Ta), titanium nitride (TiN), tantalum nitride (TaN), or the like. An interlevel dielectric may include one or more layers of silicon dioxide (SiO₂), a low-k dielectric, or an extremely low-k dielectric. A low-K dielectric is one having a smaller dielectric constant than silicon dioxide (SiO₂). Examples of low-k dielectrics include organosilicate glasses (OSG) such as carbon-doped silicon dioxide, fluorine-doped silicon dioxide (otherwise referred to as fluorinated silica glass (FSG), organic polymer low low-K dielectrics, and porous silicate glass. A metal interconnect structure may also include etch stop layers. An etch stop layer may be aluminum oxide (AlOx), silicon nitride (SiN), silicon carbide (SiC), silicon carbonitride (SiCN), silicon oxycarbide (SiOC), silicon oxycarbonitiride (SiOCN), combinations thereof, or the like.

The uppermost layer of the of the first metal interconnect structure 133 is a bonding layer 509. The bonding layer 509 includes contact pads 131 and dielectric 507. The contact pads 131 may be one of the metals mentioned as suitable for wires. In some embodiments, the contact pads 131 are a metal that is suitable for metal-to-metal bonding. In some embodiments, the dielectric 507 is silicon dioxide (SiO₂), silicon oxynitride (SiON), the like, or some other dielectric suitable for dielectric-to-dielectric bonding.

With reference to the cross-sectional view 500B of FIG. 5B, FEOL processing of the second device layer 185 provides the transistors 165, the isolation structures 515, and the dielectric structure 128. In addition to the etch stop layer 116, the dielectric structure 128 may include a first oxide layer 513 and a second oxide layer 511. These oxide layers may be silicon dioxide (SiO₂), the like, or some other suitable dielectric(s). BEOL processing provides the second metal interconnect structure 137. The uppermost layer of the second metal interconnect structure 137 is the bonding layer 102. The bonding layer 102 may include the contact pads 135 and a bonding dielectric 517.

With reference to the cross-sectional view 500C of FIG. 5C, FEOL processing of the third device layer 181 provides the transistors 159, other components of an ASIC (not shown), and the isolation structures 521. BEOL processing provides the third metal interconnect structure 151 which includes wires 525 and interlevel dielectric 529. The uppermost layer of the third metal interconnect structure 151 is the bonding layer 527. The bonding layer 527 may include the contact pad 171 and 177, other contact pads, and a bonding dielectric 523.

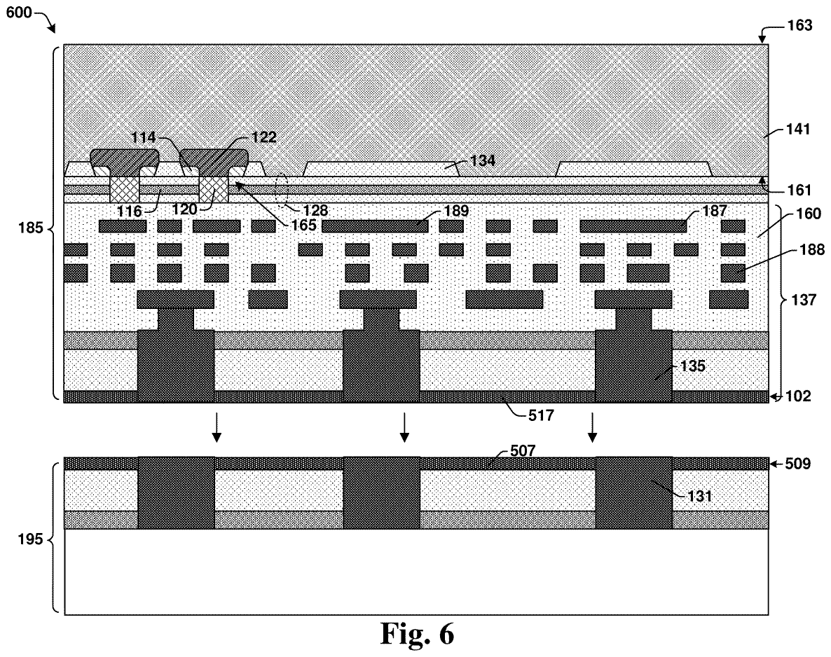

As shown by the cross-sectional view 600 of FIG. 6, the process may continue with bonding of the second device layer 185 to the first device layer 195. The bonding may be dielectric-to-dielectric bonding between the bonding dielectric 517 and the bonding dielectric 507, metal-to-metal bonding between the contact pads 135 and the contact pads 131, or both dielectric-to-dielectric and metal-to-metal bonding. In either case, electrical connections are formed between the contact pads 135 and the contact pads 131.

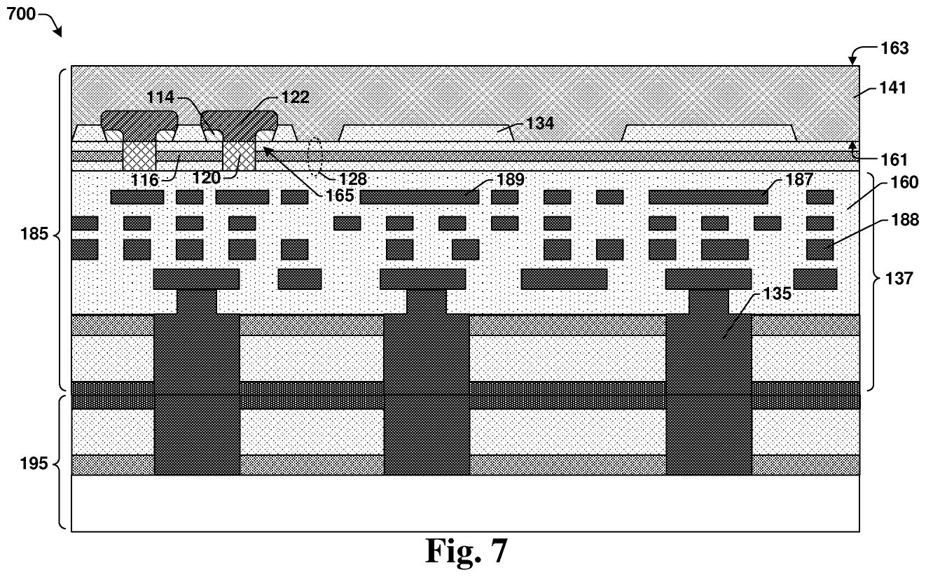

As shown by the cross-sectional view 700 of FIG. 7, the second semiconductor substrate 141 may then be thinned from the back side 163. The second semiconductor substrate 141 may be thinned by etching, mechanical grinding, CMP, the like, or some other suitable process or processes. In some embodiments, thinning reduces the second semiconductor substrate 141 to a thickness in the range from about 1 μm to about 10 μm. In some embodiments, thinning reduces the second semiconductor substrate 141 to a thickness of about 5 um or less. In some embodiments, thinning reduces the second semiconductor substrate 141 to a thickness of about 3 μm or less. If the second semiconductor substrate 141 is left too thick, it may be impractical to form TSVs and TSMIMs. If the second semiconductor substrate 141 is left too thin, it may be structurally unstable.

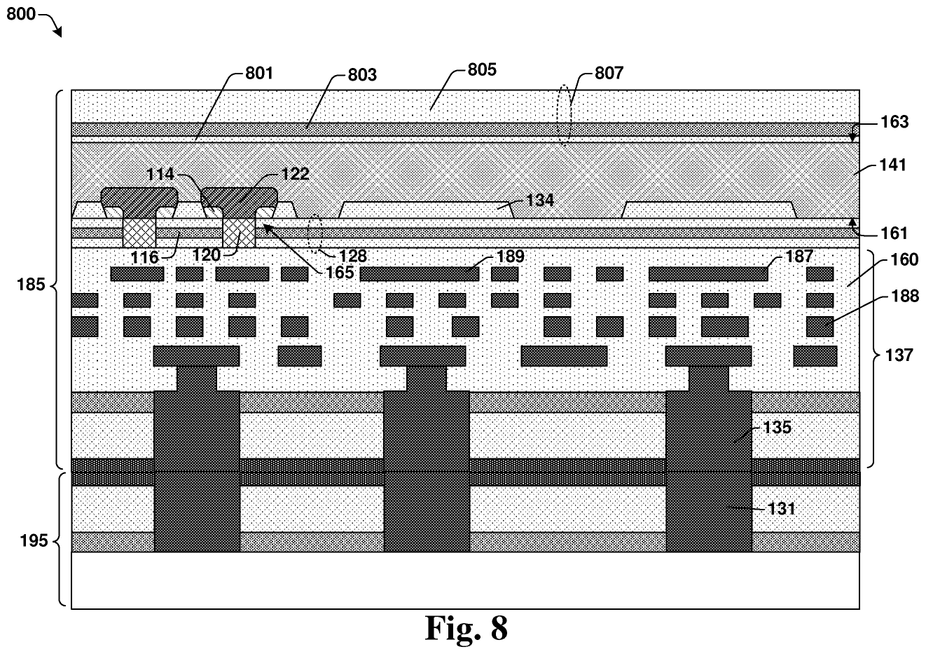

As shown by the cross-sectional view 800 of FIG. 8, a dielectric structure 807 may be formed on the back side 163 to provide isolation and passivation. The dielectric structure 807 may include, for example, a first oxide layer 801, a high k dielectric layer 803, and a second oxide layer 805. These layers may be formed by physical vapor deposition (PVD), chemical vapor deposition (CVD), atomic layer deposition (ALD), the like, or any other suitable process or processes.

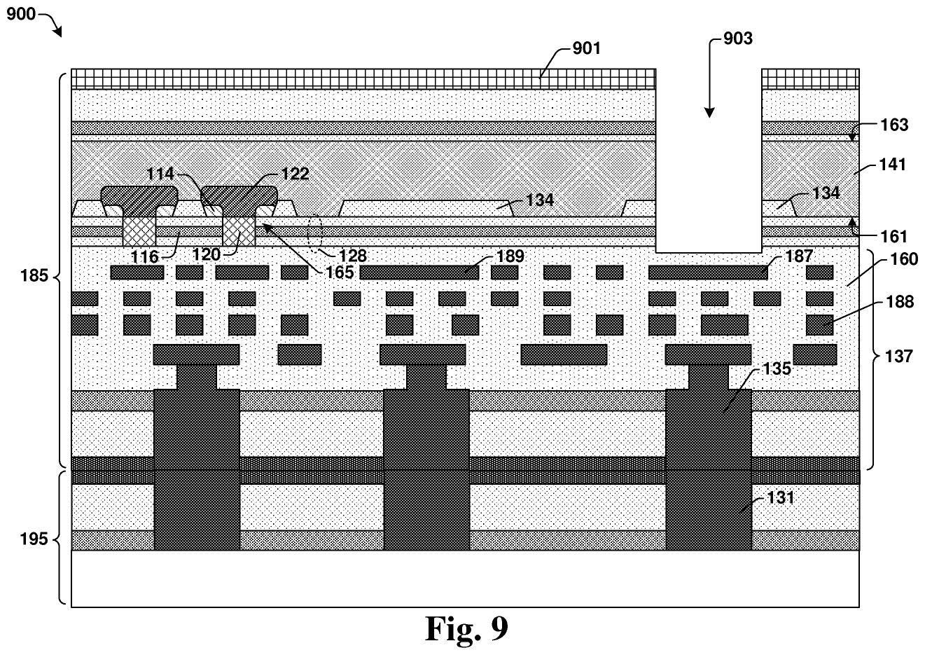

As shown by the cross-sectional view 900 of FIG. 9, a mask 901 may be formed and used to etch trenches 903. The mask 901 and other masks used in processes of this disclosure may be or comprise a photoresist, a hard mask, or the like. The mask 901 and other masks used in processes of this disclosure may be patterned by photolithography, ion beam lithography, the like, or some other suitable process. The etch process may be a dry etch such as a plasma etch, the like, or some other suitable etch process. The etch stop layer 116 may help control the depth of the trench 903. After etching the trench 903, the mask 901 may be stripped.

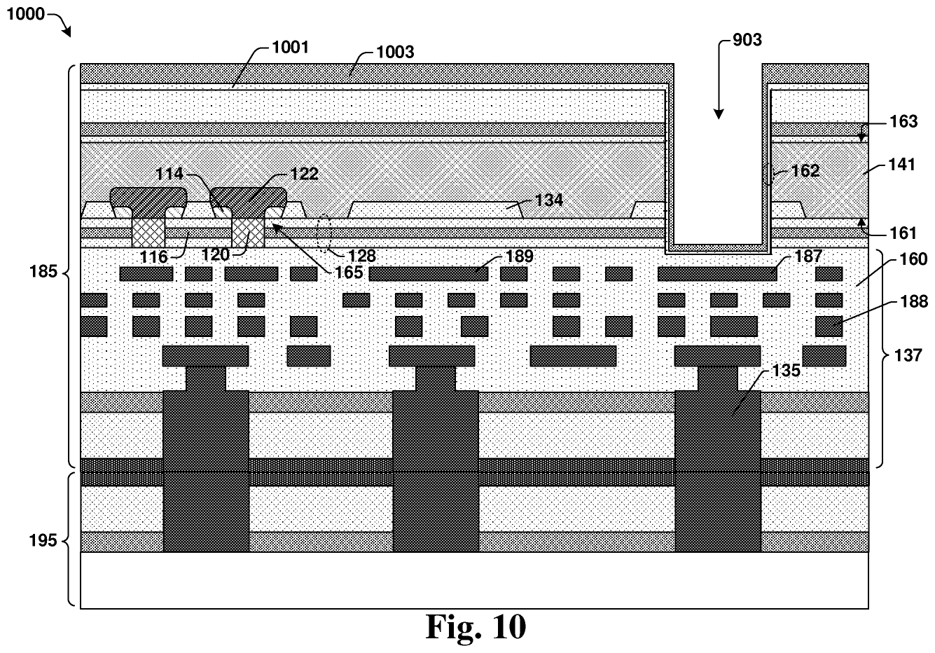

As shown by the cross-sectional view 1000 of FIG. 10, the first dielectric structure 162 may be formed so as to line the trench 903. The first dielectric structure 162 may include, for example, silicon oxide (SiO) layer 1001, and a silicon nitride (SiN) layer 1003, or any other suitable combination of layers that provides suitable adhesion, electrical isolation, and diffusion barriers as needed. These layers may be formed by PVD, CVD, ALD, the like, or any other suitable process or processes. One or more of these layers may be formed so that the first dielectric structure 162 has a greater layer thickness over the back side than in the trench 903.

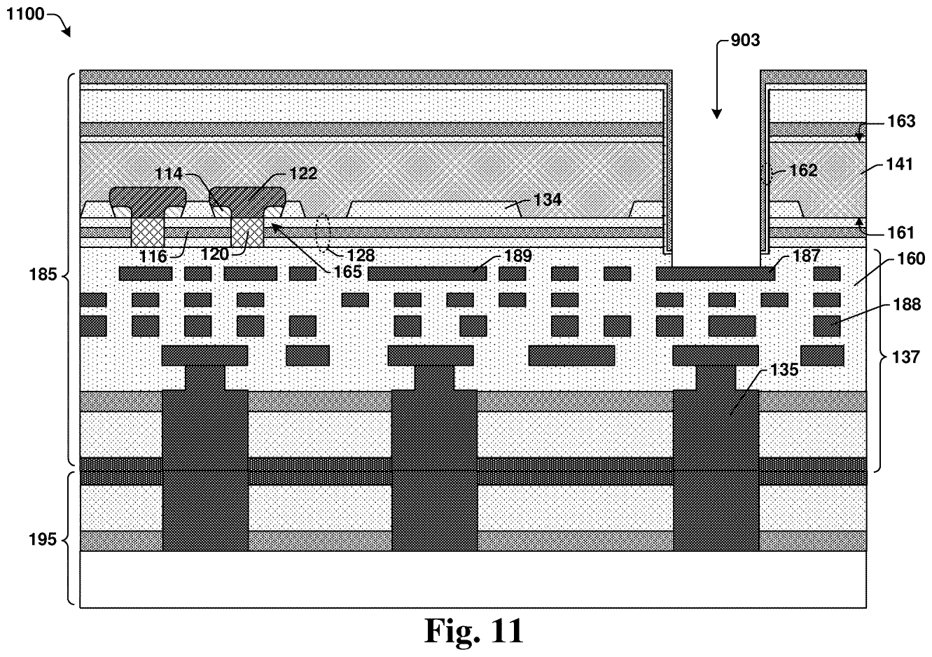

As shown by the cross-sectional view 1100 of FIG. 11, an etch process may be carried out to break through the first dielectric structure 162 and exposed the wire 187 at the bottom of the trench 903. The etch process may be an anisotropic plasma etch that avoid removing the first dielectric structure 162 from the sidewalls of the trench 903.

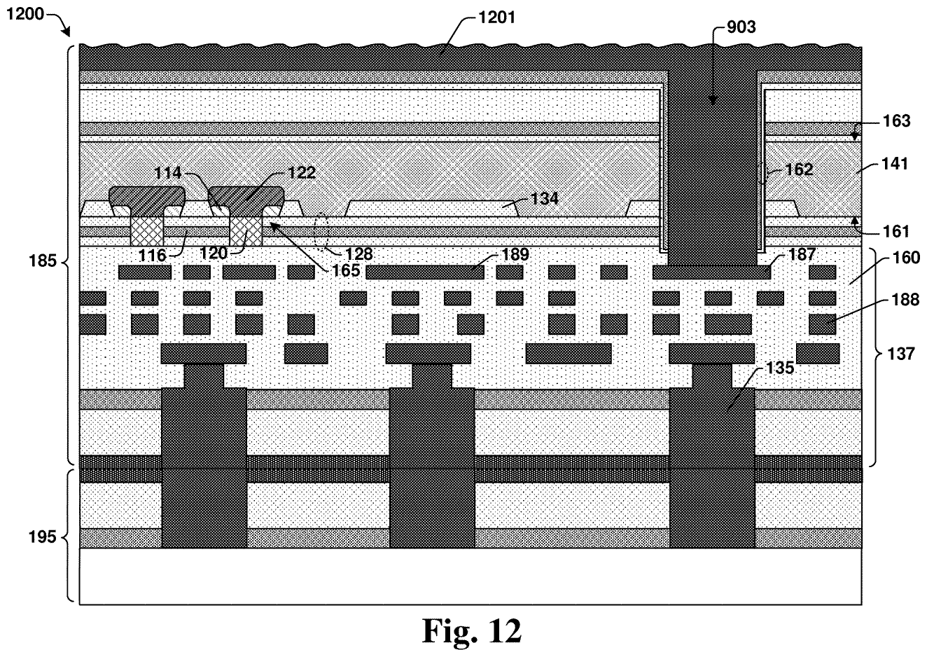

As shown by the cross-sectional view 1200 of FIG. 12, a deposition process may be carried out to fill the trench 903 with conductive material 1201. The conductive material 1201 may be doped polysilicon, a metal, or some other suitable conductor. If the conductive material 1201 is a metal, the metal may be or comprise, for example, copper (Cu), aluminum (Al), silver (Ag), tin (Sn), Indium (In), nickel (Ni), or the like. The conductive material 1201 may be deposited by electroplating, electroless plating, ALD, CVD, PVD, the like, or any other suitable processes.

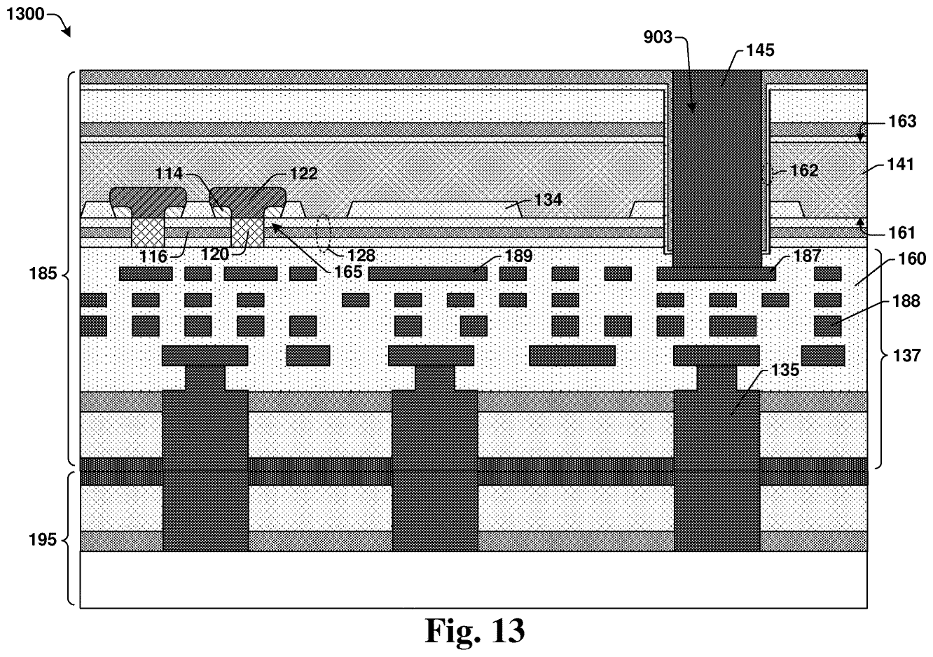

As shown by the cross-sectional view 1300 of FIG. 13 a planarization process may be carried out to remove the conductive material 1201 that deposited outside the trench 903. The conductive material 1201 that remains in the trench 903 provides the TSV 145. The planarization process may be chemical mechanical polishing (CMP), the like, or some other suitable process.

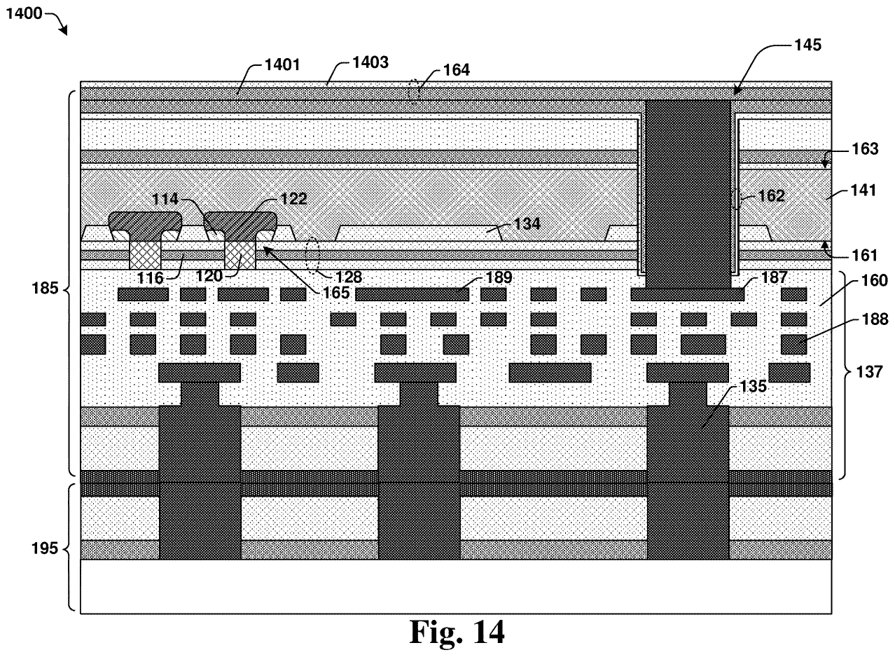

As shown by the cross-sectional view 1400 of FIG. 14, a dielectric structure 164 may be formed to cover the TSV 145. The dielectric structure 164 may include, for example, a silicon nitride (SiN) layer 1401, a silicon oxide (SiO) layer 1403, or any other suitable combination of layers that provides sufficient adhesion and electrical isolation. These layers may be deposited by PVD, CVD, ALD, the like, or any other suitable process or processes.

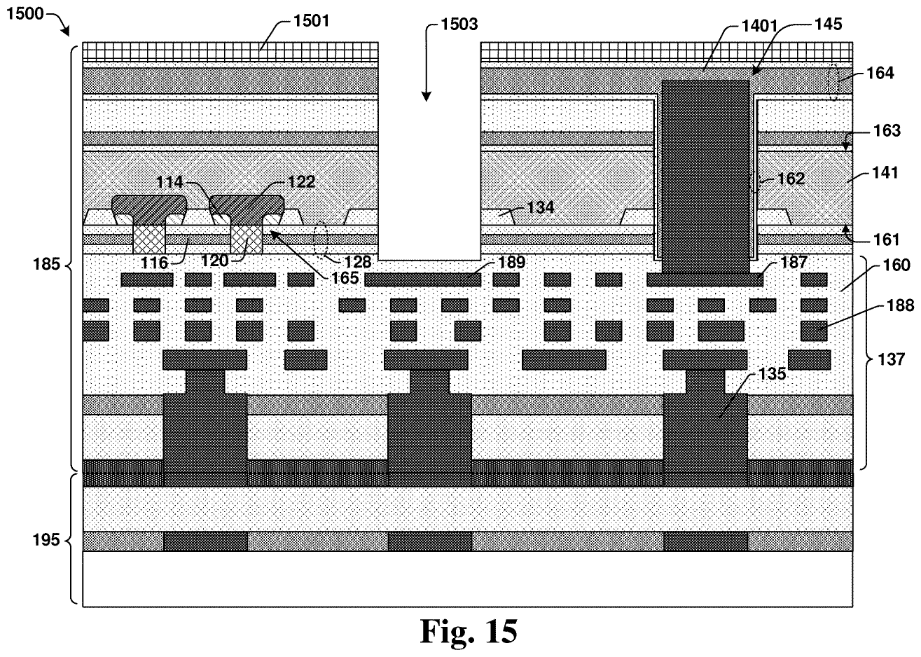

As shown by the cross-sectional view 1500 of FIG. 15, a mask 1501 may be formed and used to etch the trench 1503. The trench 1503 may have a high aspect ratio. In some embodiments, the trench 1503 has an aspect ratio in the range from about 10:1 to about 20:1. In some embodiments, the trench 1503 has an aspect ratio in the range from about 20:1 to about 30:1. If the aspect ratio is too high, the manufacturing process may be too difficult to reliably execute. If the aspect ratio is too low, it may not be possible to form a plurality of trenches 1503 with sufficient area density.

The trench 1503 may be etched by any suitable process. In some embodiments, the etch process is a dry etch. In some embodiments, the etch process includes deep reactive ion etching (DRIE), or the like. In some embodiments, the etch process includes a combination of an anisotropic plasma etching that deepens the trench 1503 and a chemical reaction that deposits a passivation layer on the sidewalls of the trench 1503, which thereby limits lateral etching that tends to widen already formed portions of the trench 1503 as the trench 1503 is being deepened. Regardless of the process used, the trench 1503 is generally wider at the back side 163 than at the front side 161 as a result of having been formed from the back side. After etching the trench 1503, the mask 1501 may be stripped.

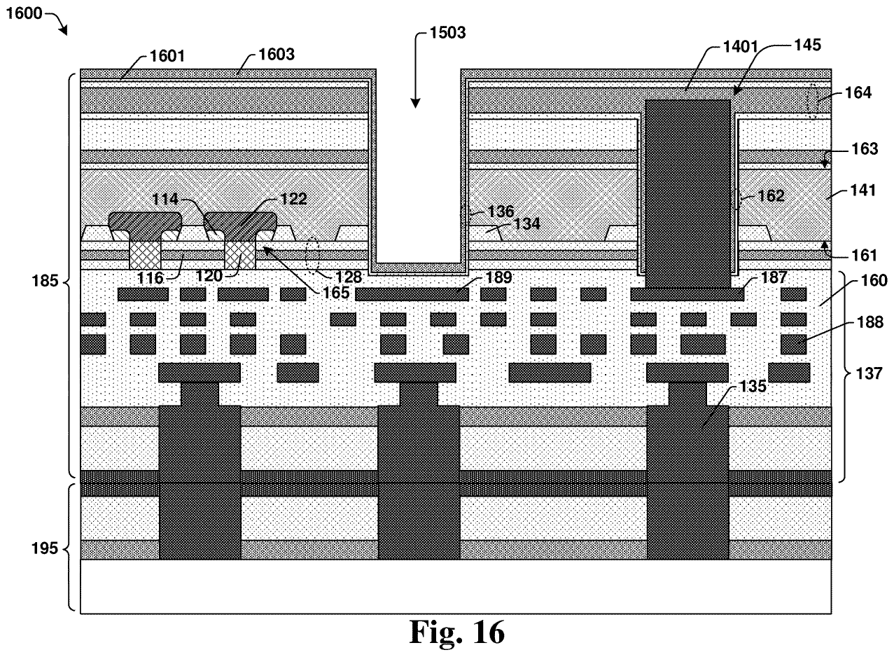

As shown by the cross-sectional view 1600 of FIG. 16, the second dielectric structure 136 may be formed so as to line the trench 1503. The second dielectric structure 136 may include, for example, a silicon oxide (SiO) layer 1601, a silicon nitride (SiN) layer 1603, or any other suitable combination of layers that provides adhesion, electrical isolation, and diffusion barriers as needed. These layers may be deposited by PVD, CVD, ALD, the like, or any other suitable process or processes. One or more of these layers may be formed so that the second dielectric structure 136 has a greater layer thickness over the back side than in the trench 1503.

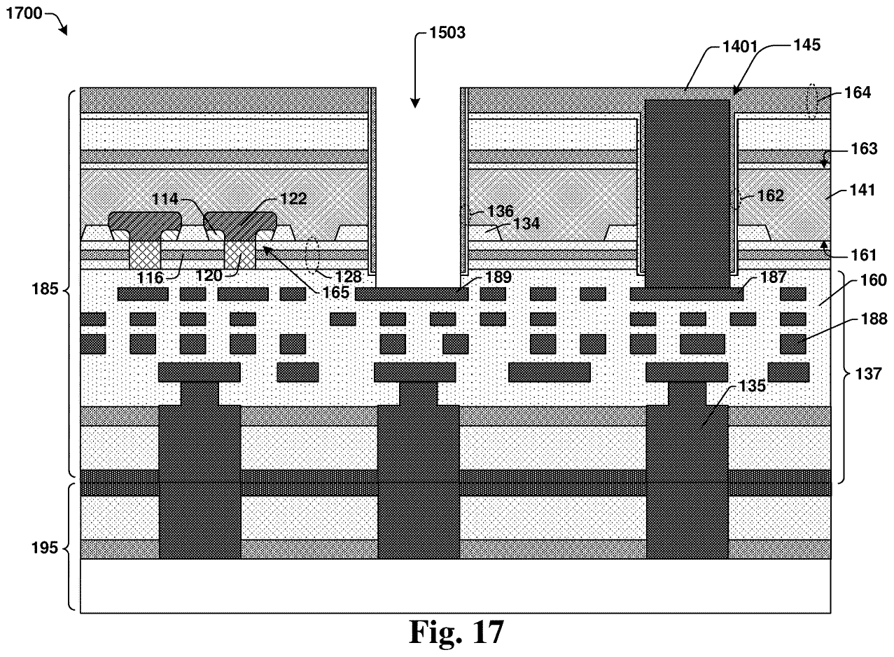

As shown by the cross-sectional view 1700 of FIG. 17, an etch process may be carried out to break through the second dielectric structure 136 and exposed the wire 189 at the bottom of the trench 1503. The etch process may be an anisotropic plasma etch that breaks through to the wire 189 without removing the second dielectric structure 136 from the sidewalls of the 1503.

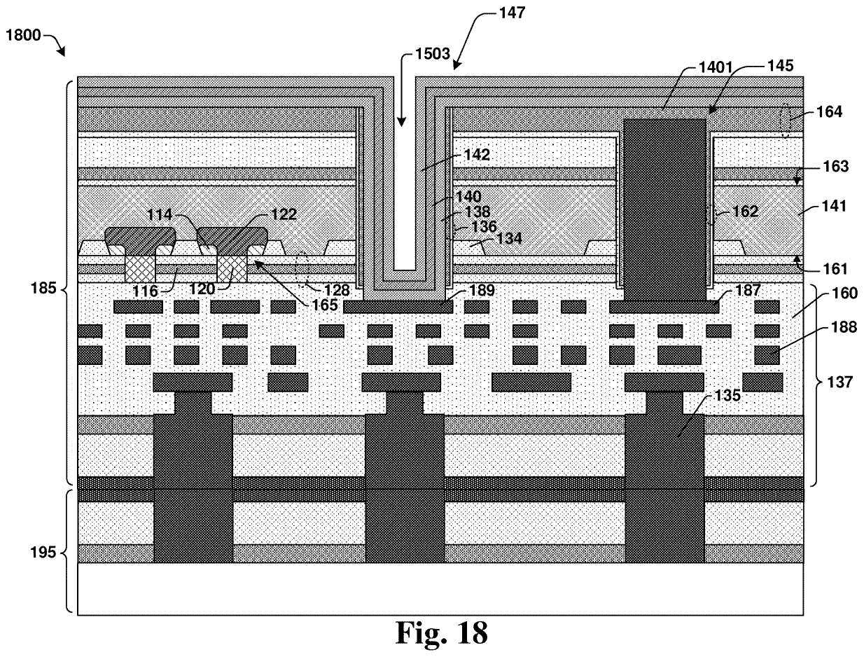

As shown by the cross-sectional view 1800 of FIG. 18, the layers of the TSMIM capacitor 147 may be deposited in the trench 1503. These include the first electrode plate 138, the capacitor dielectric layer 140, and the second electrode plate 142. Each of the first electrode plate 138 and the second electrode plate 142 may be or comprise one or more layers of titanium nitride (TiN), tungsten (W), titanium (Ti), tantalum (Ta), tantalum nitride (TaN), copper (Cu), silver (Ag), aluminum (Al), nickel (Ni), conductive alloys thereof, or the like. In some embodiments, the first electrode plate 138 includes a layer of tantalum (Ta) or tantalum nitride (TaN) and a layer of titanium nitride (TiN). In some embodiments, the second electrode plate 142 includes a layer of titanium nitride (TiN). Tantalum (Ta) and tantalum nitride (TaN) provide high conductivity and chemical stability. Titanium nitride (TiN) also provide high conductivity and chemical stability, can function as a diffusion barrier layer, and provides good adhesion to the capacitor dielectric layer 140.

In some embodiments, the first electrode plate 138 and the second electrode plate 142 have thicknesses in the range from about 1 nm to about 20 nm. In some embodiments, the first electrode plate 138 and the second electrode plate 142 have thicknesses in the range from about 20 nm to about 50 nm. If the electrode plates are too thick, they may not fit in the trench 1503. If the electrode plates are too thin, they may have too much resistance. The electrode plates may be deposited by PVD, CVD, ALD, electroplating, electroless plating, the like, or any other suitable process.

The capacitor dielectric layer 140 may be any suitable dielectric. In some embodiments, the capacitor dielectric layer 140 is a high K dielectric. Examples of high K dielectrics include, without limitation, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium oxide aluminum oxide (HfO₂—Al₂O₃), zirconium oxide (ZrO₂), tantalum oxide (Ta₂O₅), aluminum oxide (Al₂O₃), yttrium oxide(Y₂O₃), lanthanum oxide (La₂O₃), strontium titanium oxide (SrTiO₃), and the like. The capacitor dielectric layer 140 may be deposited by PVD, CVD, ALD, the like, or any other suitable process.

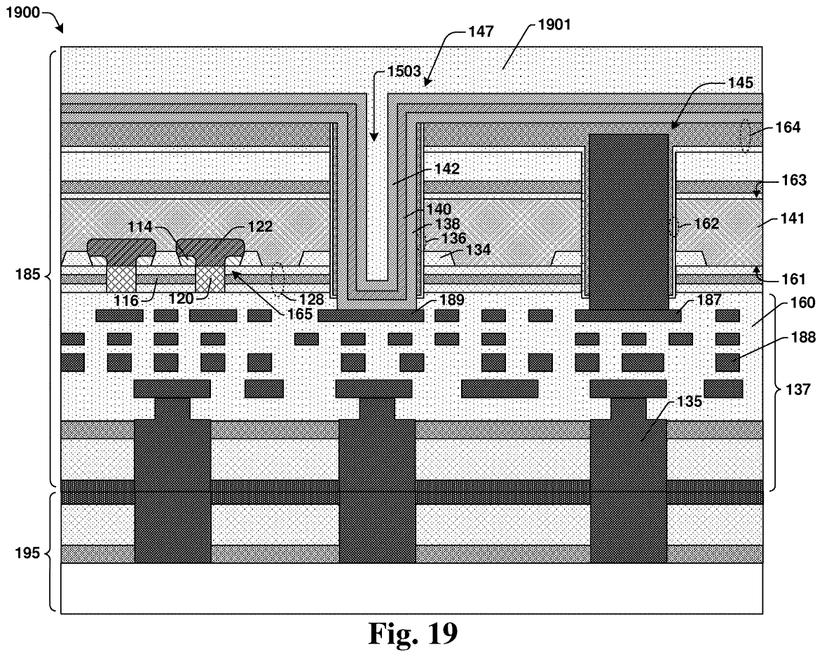

As shown by the cross-sectional view 1900 of FIG. 19, a dielectric 1901 may be deposited so as to fill any remaining space in the trench 1503. The dielectric may be silicon oxide (SiO), the like, or any other suitable dielectric. The dielectric 1901 may be deposited by PVD, CVD, ALD, the like, or any other suitable process. After deposition the dielectric 1901 may be planarized by CMP, the like, or any other suitable process.

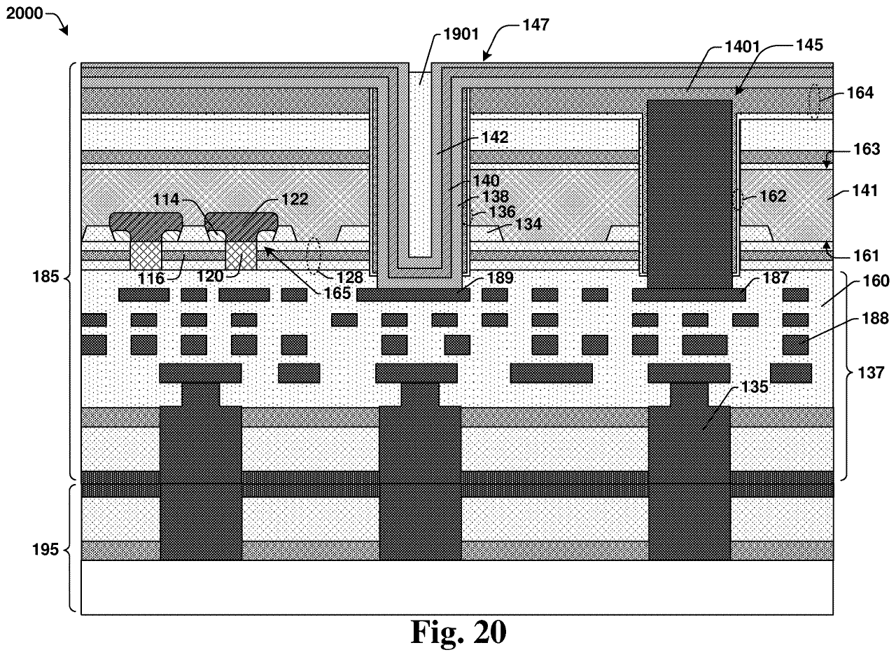

As shown by the cross-sectional view 2000 of FIG. 20, an etch process may be carried out to expose the second electrode plate 142. The etch process may be plasma etching, the like, or any other suitable process. The etch process stops on or in the second electrode plate 142 and may thin the second electrode plate 142 over the back side 163.

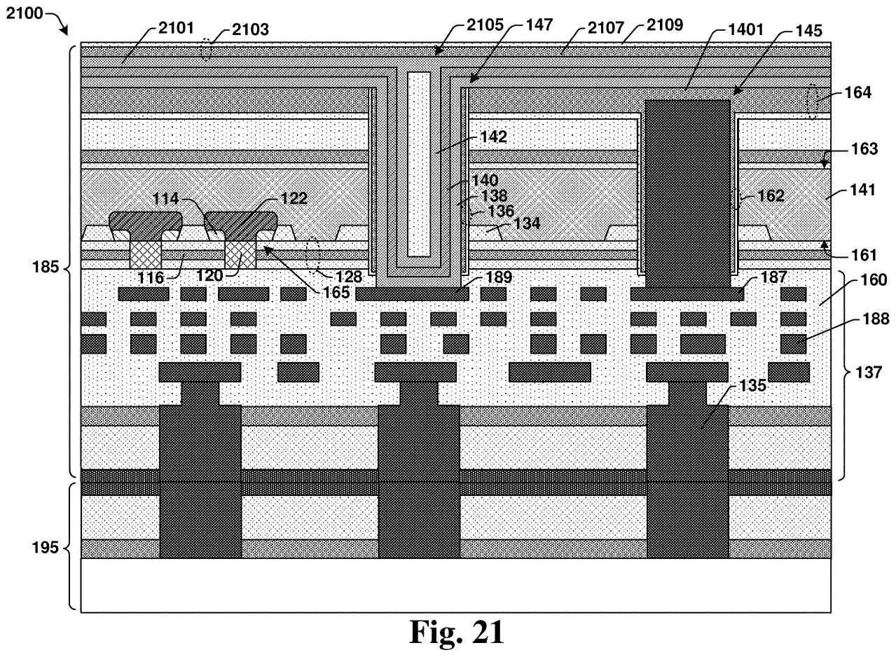

As shown by the cross-sectional view 2100 of FIG. 21, an additional layer of electrode metal 2101 and a dielectric structure 2103 may be deposited so as to thicken the second electrode plate 142 over the back side 163 and form a contact plate 2105 directly over the TSMIM capacitor 147. The additional layer of electrode metal 2101 may be deposited by PVD, CVD, ALD, electroplating, electroless plating, the like, or any other suitable process. The dielectric structure 2103 may include, for example, a silicon nitride (SiN) layer 2107, silicon oxide (SiO) layer 2109, or any other combination of layers that provides suitable adhesion and electrical isolation. The dielectric structure 2103 may be deposited by PVD, CVD, ALD, the like, or any other suitable process or processes.

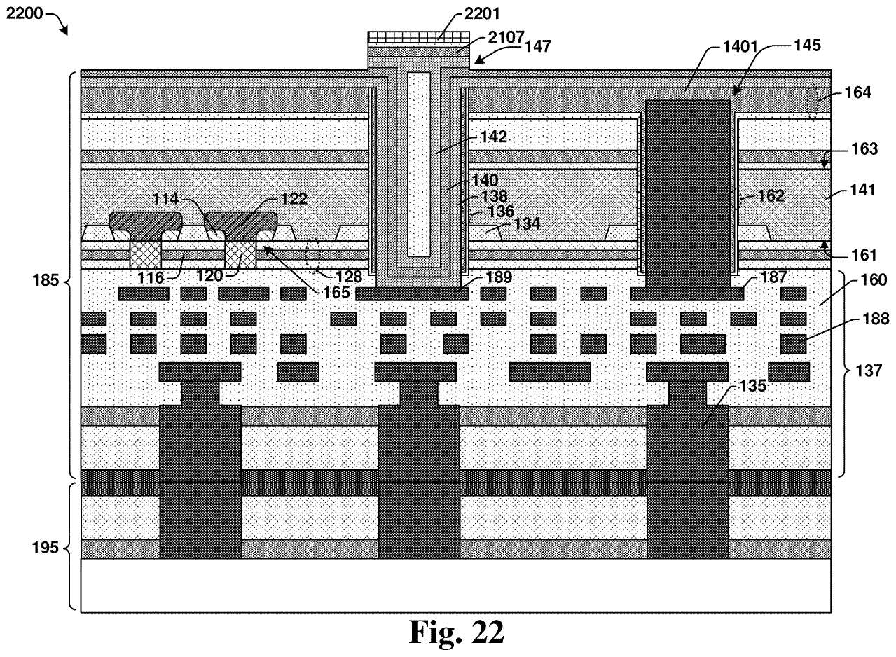

As shown by the cross-sectional view 2200 of FIG. 22, a mask 2201 may be formed and used to etch through the second electrode plate 142. The etch may stop on the capacitor dielectric layer 140. The etch process may be a plasma etch, the like, or any other suitable etch process. After etching, the mask 2201 may be stripped.

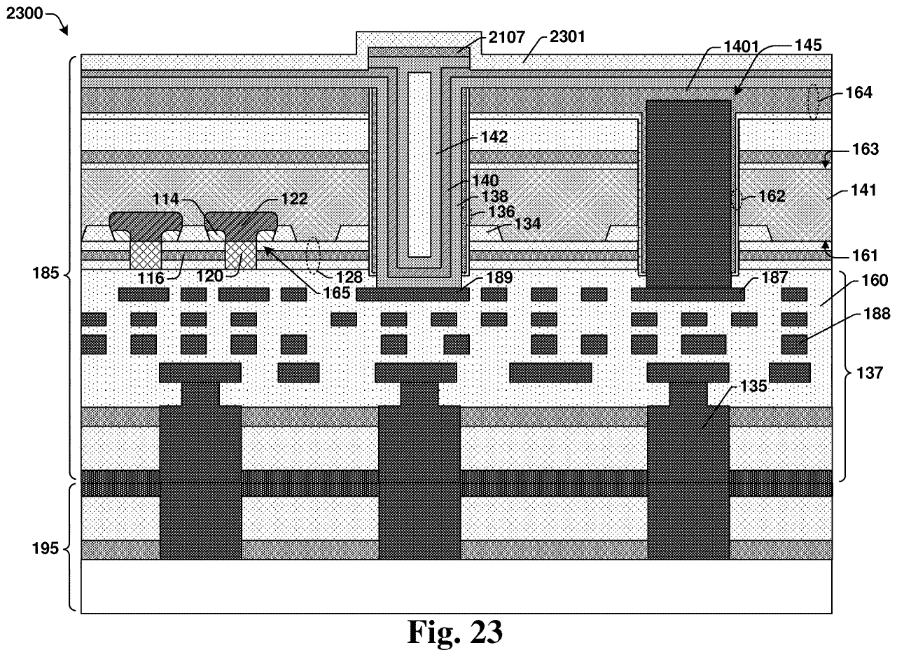

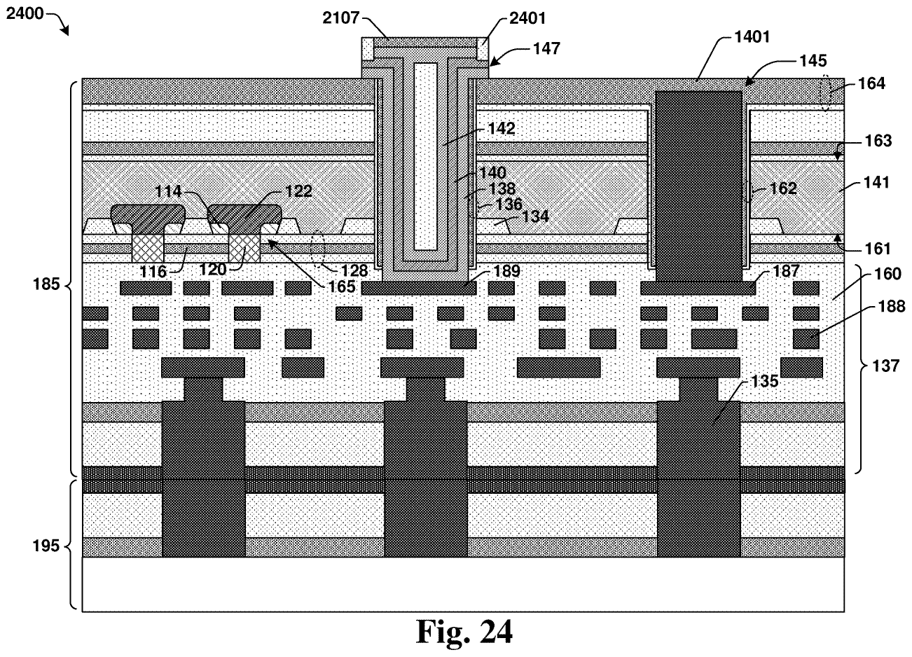

As shown by the cross-sectional view 2300 of FIG. 23, a spacer dielectric 2301 may be deposited over the structure shown by the cross-sectional view 2200 of FIG. 22. The spacer dielectric 2301 may silicon oxide (SiO), silicon nitride (SiN), the like, or any other suitable material. As shown by the cross-sectional view 2400 of FIG. 24, an etch process may be carried out the stops on the dielectric structure 164 and removes the spacer dielectric 2301 except for a portion that provides a spacer 2401 that covers the edges of the second electrode plate 142. The etch process may remove the capacitor dielectric layer 140 and the first electrode plate 138 from areas outside the coverage of the spacer 2401 and the SiN layer 2107.

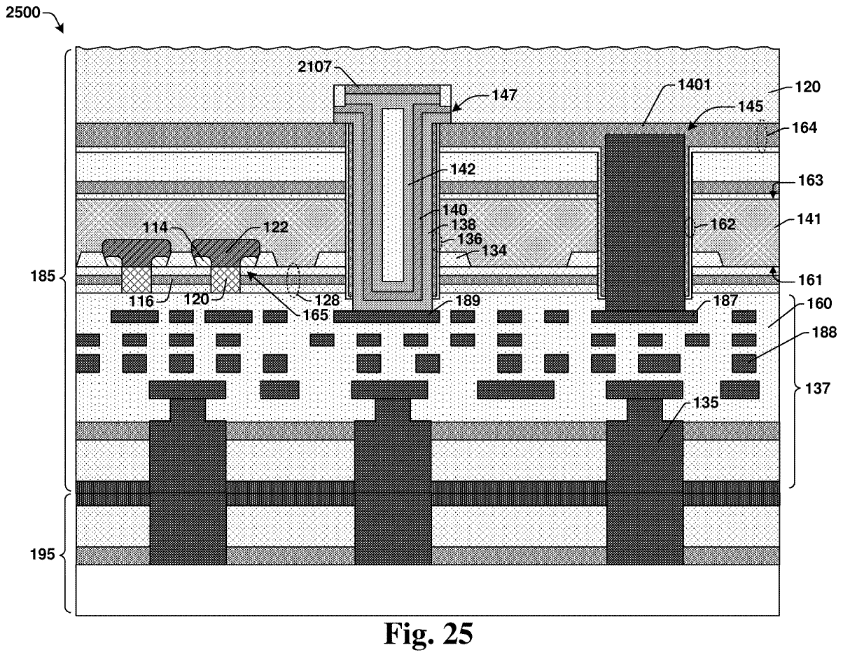

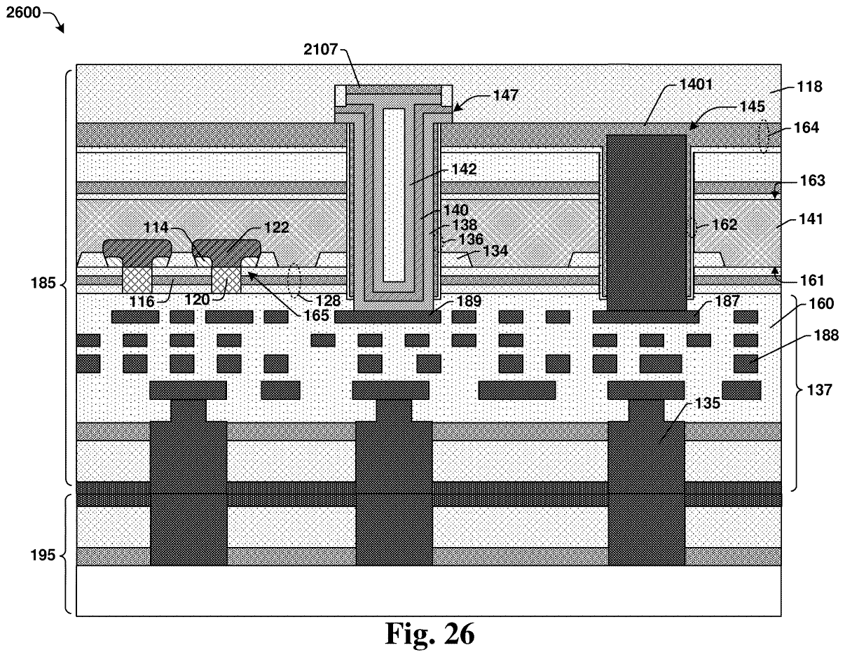

As shown by the cross-sectional view 2500 of FIG. 25, the oxide layer 118 may be deposited over the structure shown by the cross-sectional view 2400 of FIG. 24 followed by planarization as shown in the cross-sectional view 2600 of FIG. 26. The oxide layer 118 may be silicon oxide (SiO), the like, or any other suitable dielectric. The oxide layer 118 may be deposited by PVD, CVD, ALD, the like, or any other suitable process.

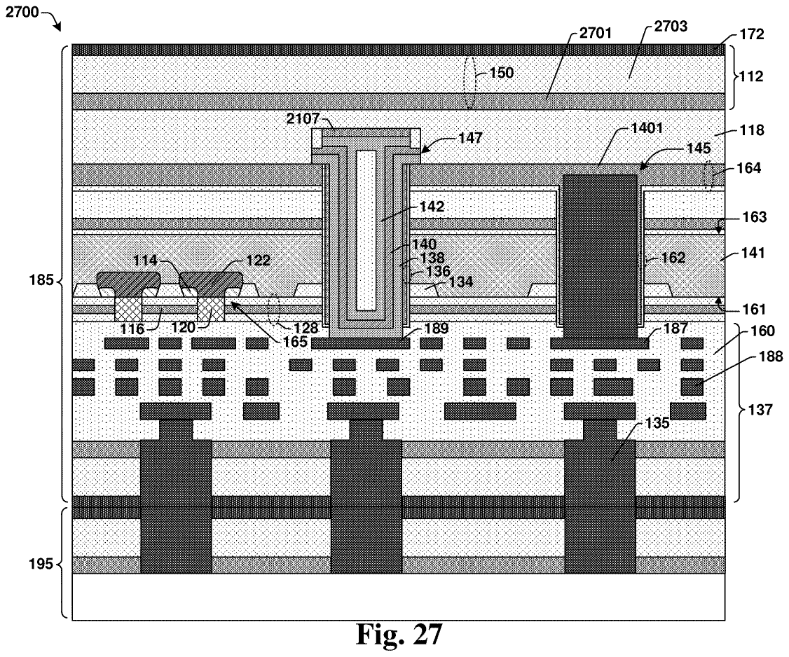

As shown by the cross-sectional view 2700 of FIG. 27, the bonding layer 112 may be formed over the oxide layer 118. The bonding layer 112 includes a passivation stack 150 and the bonding dielectric 172. The passivation stack 150 may include one or more layers that provide a barrier against contamination, electrical insulation, mechanical stability, or other such properties. The passivation stack 150 may include, for example, a layer 2701 of silicon nitride (SiN) or the like, a layer 2703 of silicon oxide (SiO) or the like, or any other suitable layers. The bonding dielectric 172 may be silicon oxynitride (SiON), the like, or any other suitable dielectric. The passivation stack 150 and the bonding dielectric 172 may be deposited by PVD, CVD, ALD, the like, or any other suitable process or processes.

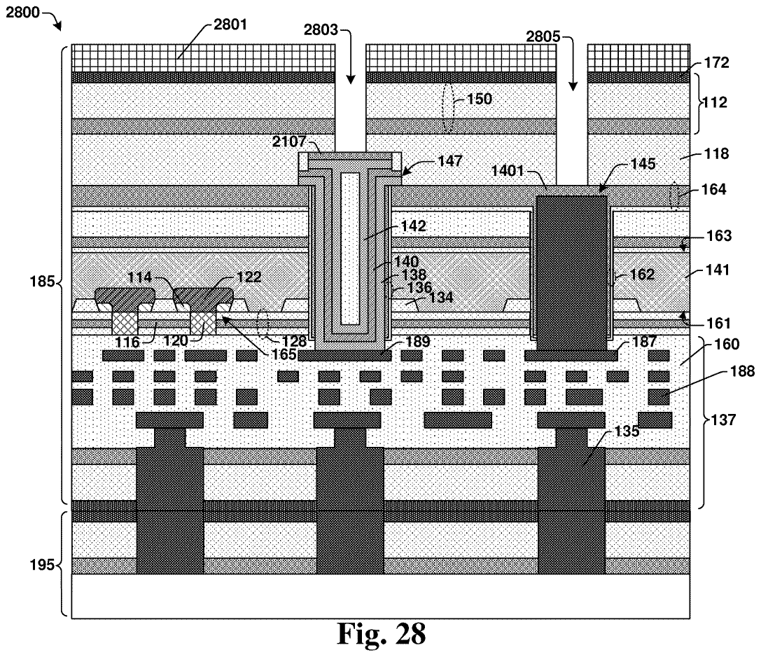

As shown by the cross-sectional view 2800 of FIG. 28, a mask 2801 may be formed and used to etch a hole 2803 through to the TSMIM capacitor 147 and a hole 2805 through to the TSV 145. The etching process may temporarily stop on the SiN layer 2107 and the SiN layer 1401 so that a difference in depth between the hole 2803 and the hole 2805 is accommodated by a difference in time etching through the oxide layer 118. After etching, the mask 2801 may be stripped.

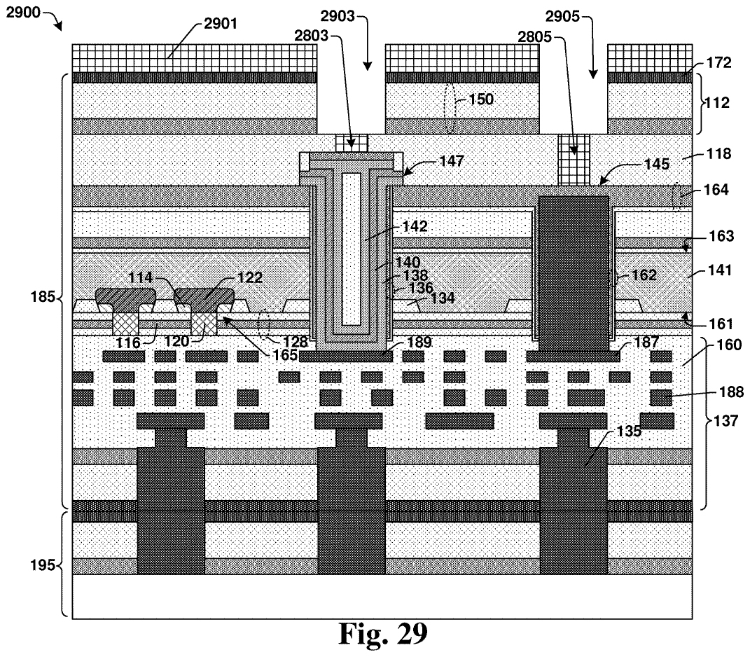

As shown by the cross-sectional view 2900 of FIG. 29, a mask 2901 may be formed and used to etch a trench 2903 over the hole 2803 and a trench 2905 over the hole 2805. The mask 2901 may fill portions of the holes 2803 and 2805. After etching, the mask 2901 may be stripped.

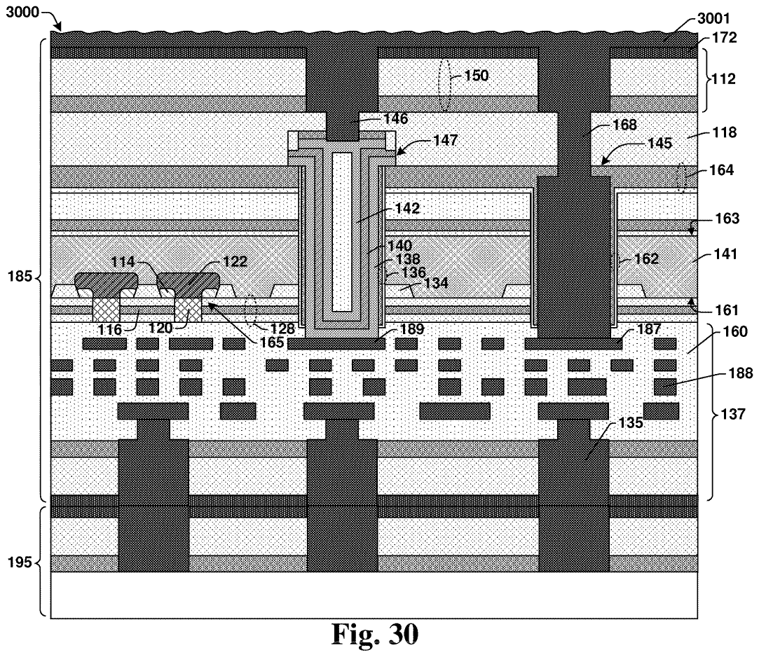

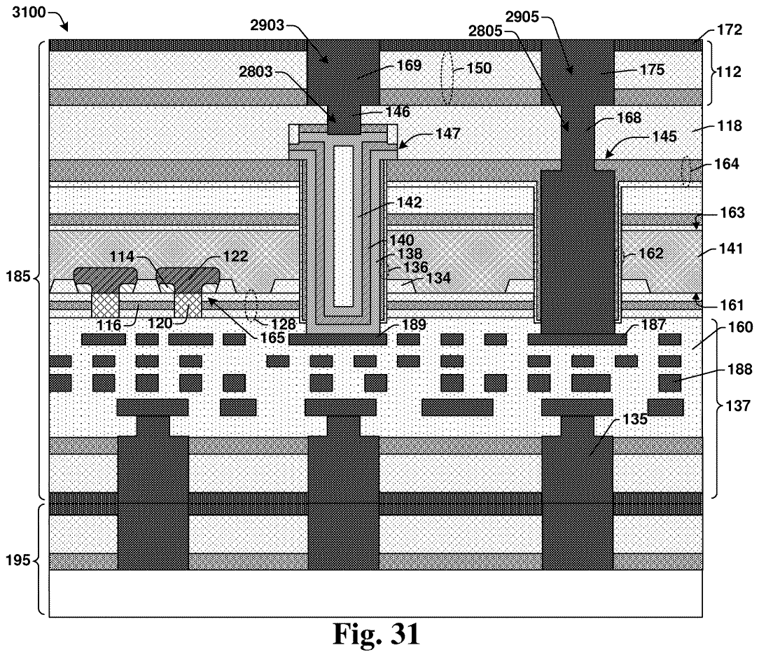

As shown by the cross-sectional view 3000 of FIG. 30, a metal 3001 may be deposited so at to fill the trenches 2903 and 2905 and the holes 2803 and 2805. The metal 3001 may be copper (Cu) or any type of metal suitable for the wires 188. The metal 3001 may be deposited by PVD, CVD, ALD, electroplating, electroless plating, the like, or any other suitable process. As shown by the cross-sectional view 3100 of FIG. 31, a planarization process may be used to remove metal 3001 that deposited outside the trenches 2903 and 2905 and the holes 2803 and 2805. The planarization process map be CMP, the like, or any other suitable process. The metal 3001 that remains in the trench 2903 provides the contact pad 169. The metal 3001 that remains in the hole 2803 provides a via 146 that connects the contact pad 169 to an electrode of the TSMIM capacitor 147. The metal 3001 that remains in the trench 2905 provides the contact pad 175. The metal 3001 that remains in the hole 2803 provides a via 168 that connects the contact pad 175 to the TSV 145. The via 168 is longer than the via 146.

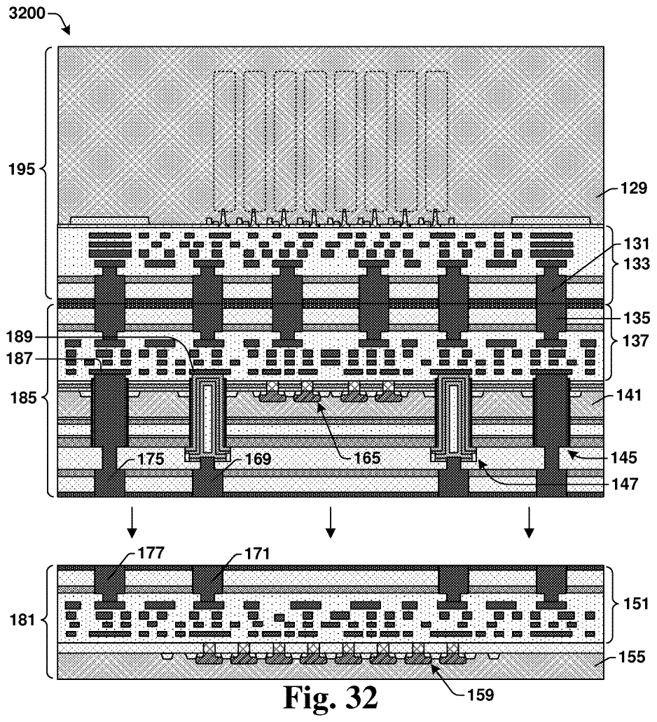

As shown by the cross-sectional view 3200 of FIG. 32, the second device layer 185, with the first device layer 195 attached, may be bonded to the third device layer 181. The bonding may be dielectric-to-dielectric bonding, metal-to-metal bonding, or both dielectric-to-dielectric and metal-to-metal bonding. In either case, the bonding may be carried out in such a way that electrical connections are formed between the contact pad 175 and the contact pad 177 and between the contact pad 169 and the contact pad 171.

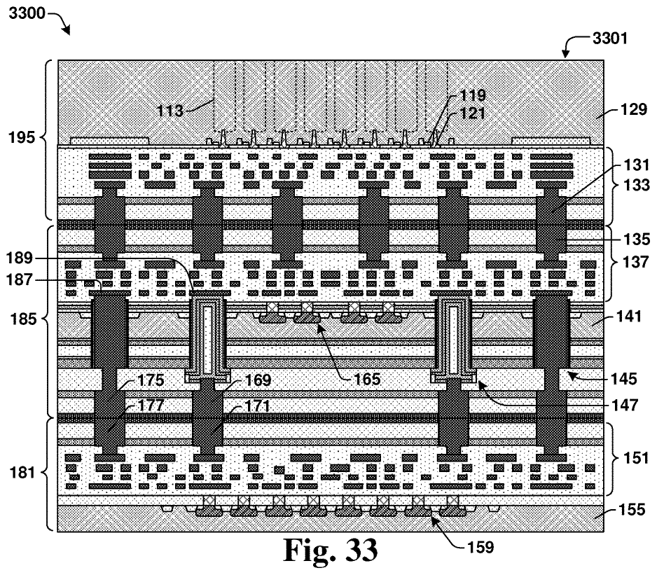

As shown by the cross-sectional view 3300 of FIG. 33, the first semiconductor substrate 129 may then be thinned from the back side 3301. The first semiconductor substrate 129 may be thinned by etching, mechanical grinding, CMP, the like, or some other suitable process or processes. In some embodiments, thinning reduces the second semiconductor substrate 141 to a thickness in the range from about 1 μm to about 10 μm. In some embodiments, thinning reduces the first semiconductor substrate 129 to a thickness of about 5 um or less. In some embodiments, thinning reduces the second semiconductor substrate 141 to a thickness of about 3 μm or less. If the first semiconductor substrate 129 is left too thick, light may not effectively penetrate to the photodiodes 113. If the first semiconductor substrate 129 is left too thin, light may not be efficiently captured by the photodiodes 113.

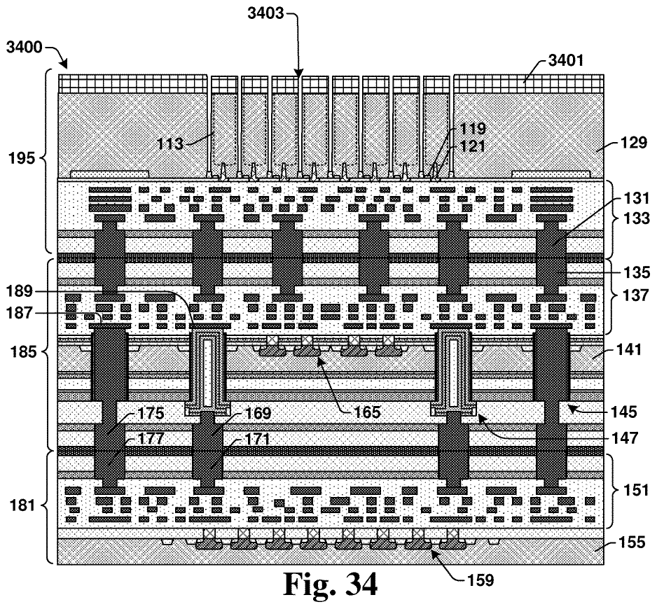

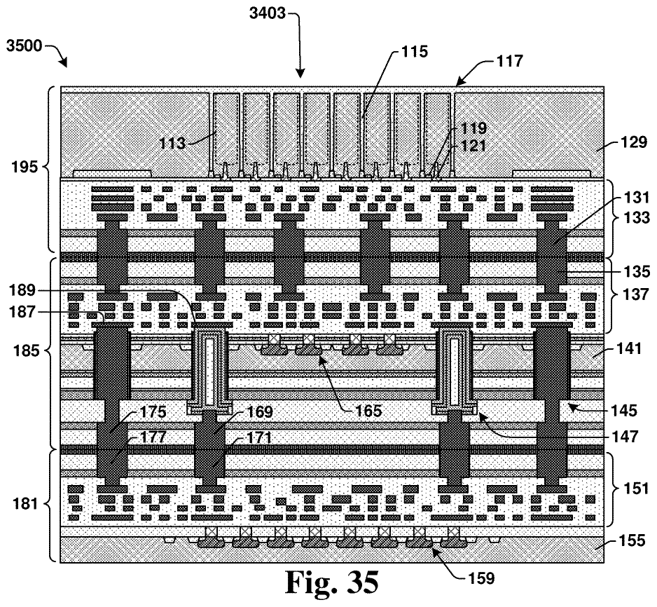

As shown by the cross-sectional view 3400 of FIG. 34, a mask 3401 may be formed and used to etch trenches 3403 for electrical isolation between the photodiodes 113. After etching, the mask 3401 may be stripped. As shown by the cross-sectional view 3500 of FIG. 35, the trenches 3403 may be filled to provide a back side deep trench isolation (BDTI) structure 115. The BDTI structure may be entirely dielectric or have just a dielectric liner. The dielectric liner may include a high k dielectric. The BDTI structure may be deposited by PVD, CVD, ALD, electroplating, electroless plating, the like, or any other suitable process or processes. With reference to FIG. 1A, further processing may form the back side metal grid 107, the color filters 109, microlenses 105, and the contact pads 125.

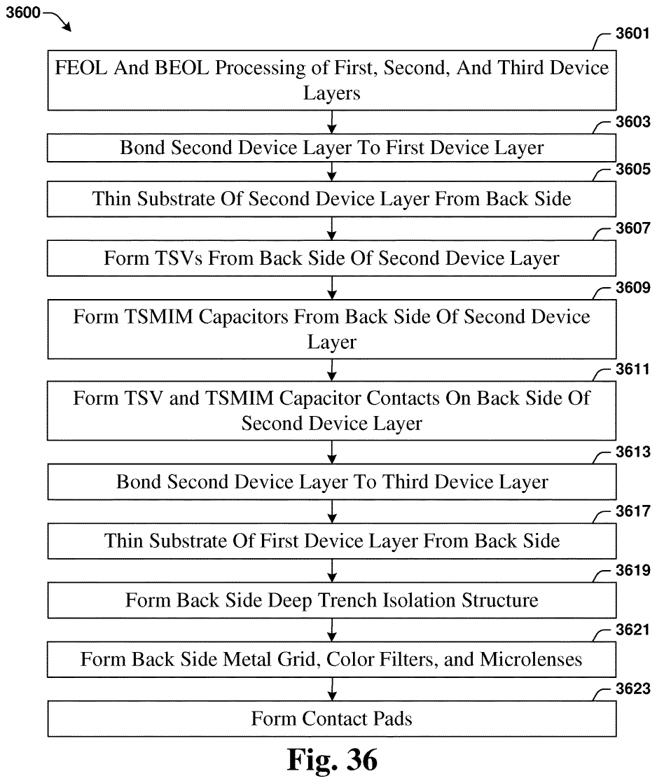

FIG. 36 provides a flow diagram for a process 3600 of forming an image sensor of the present disclosure. While the process 3600 is illustrated and described below as a series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The process 3600 begins act 3601, which is FEOL processing of first, second, and third device layers. The cross-sectional views 500A-500C of FIGS. 5A-5C provide examples of these device layers after this initial processing. Each of the device layers may be a separate wafer at this stage of processing. FEOL processing forms wells, transistors, diode, isolation structures, and the like in the substrates. BEOL processing forms metal interconnect structures. The first device layer may contain an array of photodiodes or other photodetector structures, transfer gates, and the like. The second device layer may include some photodetector pixel circuit components and row drivers and column readout circuits for the photodiode array. The column readout circuits may include correlated double sampling circuits, amplifiers, analog-to-digital converts, and/or the like. The third device layer may include an ASIC.

Act 3603 is aligning the first and second device layers and bonding them together through their respective bonding layers. The cross-sectional view 600 of FIG. 6 provides an example.

Act 3605 is thinning the semiconductor substrate of the second device layer from the back side. The cross-sectional view 700 of FIG. 7 provides an example.

Act 3607 is forming TSVs through the semiconductor substrate of the second device layer from the back side. The cross-sectional views 800-1300 of FIGS. 8-13 provide an example.

Act 3609 is forming TSMIM capacitors through the semiconductor substrate of the second device layer from the back side. The cross-sectional views 1400-2400 of FIGS. 14-24 provide an example.

Act 3611 is forming TSV and TSMIM contacts on the back side of the second device layer. The cross-sectional views 2500-3100 of FIGS. 25-31 provide an example.

Act 3613 is aligning the second and third device layers and bonding them together so that the TSV and TSMIM contacts are coupled to the third device layer. The cross-sectional view 3200 of FIG. 32 provides an example.

Act 3617 is thinning the semiconductor substrate of the first device layer from the back side. The cross-sectional view 3300 of FIG. 33 provides an example.

Act 3619 forming a BDTI structure from the back side of the semiconductor substrate of the first device layer. The cross-sectional views 3400-3500 of FIGS. 34-35 provide an example.

Act 3621 is additional processing that forms a back side metal grid, color filters, and microlenses on the back side of the semiconductor substrate of the first device layer. Act 3623 is forming contact pads on the back side of the semiconductor substrate of the first device layer. FIG. 1A provides an example of the resulting structure.

Some aspects of the present disclosure relate to an image sensor that include first, second, and third device layers attached together. The first, second, and third device layers include semiconductor substrates and interconnect structures. The first semiconductor substrate includes a photosensitive area in a first array. A photodetector pixel circuit is in a second array having rows and columns, includes the photosensitive area on the semiconductor substrate, and a transistor on the second semiconductor substrate. A column readout circuit in the second device layer corresponds to one of the columns. A through substrate via and a through substrate MIM capacitor are formed through the second device layer. The through substrate MIM capacitor is either in the column readout circuit or in the photodetector pixel circuit.

In some embodiments, the through substrate MIM capacitor is in the photodetector pixel circuit. In some embodiments, the through substrate MIM capacitor is a lateral overflow integration capacitor. In some embodiments, the photodetector pixel circuit further comprises a floating diffusion node and four transfer gates and the photosensitive area is one of four photosensitive areas coupled to the floating diffusion node through the four transfer gates respectively. In some embodiments, the through substrate MIM capacitor is a correlated double sampling capacitor. In some embodiments, the through substrate MIM capacitor is narrower at the first side than at the second side. In some embodiments, the through substrate MIM capacitor abuts a wire in the second metal interconnect structure. In some embodiments, the second metal interconnect structure comprises an uppermost metallization layer and a next-to-uppermost metallization layer, and the uppermost metallization layer has a thickness within 50% of that of the next-to-uppermost metallization layer. In some embodiments, the through substrate MIM capacitor has an electrode plate coupled to the third device layer.

In some embodiments, the image sensor further includes a first bonding pad and a second bonding pad on the back side of the second device layer. A first via connects the through substrate MIM capacitor to the first bonding pad and a second via connects the through substrate via to the second bonding pad. In some embodiments, the second via is longer than the first via. In some embodiments, the through substrate MIM capacitor has a first electrode coupled to the second metal interconnect structure and a second electrode coupled to the third metal interconnect structure.

Some aspects of the present disclosure relate to an image sensor that include first, second, and third semiconductor substrates attached together, an array of photodetector pixel circuits arranged in rows and columns, and a correlated double sampling circuit. The photodetector pixel circuits include a photodiode in the first semiconductor substrate and a row select transistor on the second semiconductor substrate. The correlated double sampling circuit is operative for one of the columns. An MIM capacitor extends through the second semiconductor substrate and is in the correlated double sampling circuit or one of the photodetector pixel circuits.

In some embodiments, the first MIM capacitor is in the correlated double sampling circuit. In some embodiments, the image sensor further includes a second MIM capacitor extending through the second semiconductor substrate which is in the array of photodetector pixel circuits.

Some aspects of the present disclosure relate to a method of manufacturing an image sensor, the method includes providing a first semiconductor substrate, forming a photosensitive area and a floating diffusion region in the first semiconductor substrate, forming a transfer gate on the first semiconductor substrate, wherein the transfer gate is configured to selectively couple the photosensitive area to the floating diffusion region, providing a second semiconductor substrate, forming a row select transistor on a first side of the second semiconductor substrate, forming a second metal interconnect structure over the first side, attaching the first semiconductor substrate to the second semiconductor substrate, thinning the second semiconductor substrate from a second side, forming a through substrate via in the second semiconductor substrate, forming a through substrate MIM capacitor in the second semiconductor substrate, attaching the second semiconductor substrate to a third semiconductor substrate, thinning the first semiconductor substrate, and forming microlenses on the first semiconductor substrate.

In some embodiments the through substrate via is formed prior to the through substrate MIM capacitor. In some embodiments forming the through substrate MIM capacitor in the second semiconductor substrate includes etching a trench extending at least from the second side to the first side, lining the trench with dielectric, etching through a bottom of the trench to expose a wire in the second metal interconnect structure, and depositing a first electrode plate, a capacitor dielectric layer, and a second electrode plate in the trench. In some embodiments the trench is filled with dielectric that deposits over the second electrode plate. The dielectric is removed from over the second electrode plate flowed by a deposition that thickens the second electrode plate and forms a contact area for the second electrode plate. In some embodiments, the method further includes forming a mask that covers a portion of the second electrode plate, etching through the second electrode plate around the mask, forming a spacer around the portion of the second electrode plate, and etching through first electrode plate in alignment with the spacer. In some embodiments, after thickening the second electrode plate and before forming the mask, a dielectric layer is deposited over the second electrode plate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An image sensor, comprising:
a first device layer comprising a first semiconductor substrate and a first metal interconnect structure;
a second device layer bonded to the first device layer, wherein the second device layer comprises a second semiconductor substrate having a first side and a second side and a second metal interconnect structure on the first side;
a third device layer bonded to the second device layer, wherein the third device layer comprises a third semiconductor substrate and a third metal interconnect structure;
a photosensitive area in a first array in the first semiconductor substrate;
a photodetector pixel circuit in a second array having rows and columns, wherein the photodetector pixel circuit includes the photosensitive area and comprises a transistor in the second device layer;
a column readout circuit in the second device layer, wherein the column readout circuit corresponds to one of the columns;
a through substrate via in the second device layer; and
a through substrate MIM capacitor in the second device layer, wherein the through substrate MIM capacitor is in the column readout circuit or the photodetector pixel circuit.

2. The image sensor of claim 1, wherein the through substrate MIM capacitor is in the photodetector pixel circuit.

3. The image sensor of claim 2, wherein the through substrate MIM capacitor is a lateral overflow integration capacitor.

4. The image sensor of claim 3, wherein the photodetector pixel circuit further comprises a floating diffusion node and four transfer gates, wherein the photosensitive area is one of four photosensitive areas coupled to the floating diffusion node through the four transfer gates respectively.

5. The image sensor of claim 1, wherein the through substrate MIM capacitor is a correlated double sampling capacitor.

6. The image sensor of claim 1, wherein the through substrate MIM capacitor is narrower at the first side than at the second side.

7. The image sensor of claim 1, wherein the through substrate MIM capacitor abuts a wire in the second metal interconnect structure.

8. The image sensor of claim 1, wherein the second metal interconnect structure comprises an uppermost metallization layer and a next-to-uppermost metallization layer, and the uppermost metallization layer has a thickness within 50% of that of the next-to-uppermost metallization layer.

9. The image sensor of claim 1, wherein the through substrate MIM capacitor has an electrode plate coupled to the third device layer.

10. The image sensor of claim 1, further comprising:
a first bonding pad and a second bonding pad over the second side;
a first via connecting the through substrate MIM capacitor to the first bonding pad; and
a second via connecting the through substrate via to the second bonding pad, wherein the second via is longer than the first via.

11. The image sensor of claim 1, wherein the through substrate MIM capacitor has a first electrode coupled to the second metal interconnect structure and a second electrode coupled to the third metal interconnect structure.

12. An image sensor, comprising:
a first semiconductor substrate;
a second semiconductor substrate, wherein the second semiconductor substrate is attached to the first semiconductor substrate;
a third substrate, wherein the second semiconductor substrate is attached to the third substrate;
an array of photodetector pixels arranged in rows and columns, wherein the photodetector pixels comprise a photodiode in the first semiconductor substrate and a row select transistor on the second semiconductor substrate;
a column readout system, wherein the column readout system is operative for one of the columns; and
a first MIM capacitor extending through the second semiconductor substrate, wherein the first MIM capacitor is in the column decoder or one of the photodetector pixels.

13. The image sensor of claim 12, wherein the first MIM capacitor is in the column readout system.

14. The image sensor of claim 12, further comprising a second MIM capacitor extending through the second semiconductor substrate, wherein the second MIM capacitor is in one of the photodetector pixels.

15-20. (canceled)

21. An image sensor, comprising:
a first semiconductor substrate comprising an array of photosensitive regions;
a second semiconductor substrate attached to the first semiconductor substrate and having a first side and a second side;
a metal interconnect structure on the first side of the second semiconductor substrate;
a through substrate MIM capacitor extending through the second semiconductor substrate from the second side to the metal interconnect structure, wherein the through substrate MIM capacitor comprises a first electrode plate contacting a wire of the metal interconnect structure; and
wherein the metal interconnect structure comprises an uppermost metallization layer and a next-to-uppermost metallization layer, the uppermost metallization layer having a thickness no more than 50% greater than a thickness of the next-to-uppermost metallization layer.

22. The image sensor of claim 21, further comprising:
a through substrate via extending through the second semiconductor substrate;
a first contact pad coupled to the through substrate MIM capacitor by a first via; and
a second contact pad coupled to the through substrate via by a second via,
wherein the second via is longer than the first via.

23. The image sensor of claim 21, further comprising:
a through substrate via extending through the second semiconductor substrate;
a first dielectric structure separating the through substrate via from the second semiconductor substrate; and
a second dielectric structure separating the through substrate MIM capacitor from the second semiconductor substrate,
wherein a dielectric layer of the first dielectric structure extends over the second side of the second semiconductor substrate and abuts a sidewall of the second dielectric structure.

24. The image sensor of claim 21, wherein the through substrate MIM capacitor comprises a second electrode plate having a portion extending over the second side of the second semiconductor substrate, and a dielectric spacer covering an edge of the portion.

25. The image sensor of claim 21, wherein the through substrate MIM capacitor is one of a plurality of through substrate MIM capacitors forming a capacitor array having one-fourth the number density of the array of photosensitive regions.

26. The image sensor of claim 21, further comprising:
a third device layer attached to the second semiconductor substrate and comprising a third metal interconnect structure; and
a through substrate via extending through the second semiconductor substrate,
wherein a second electrode plate of the through substrate MIM capacitor is electrically coupled to the through substrate via through the third metal interconnect structure.
